(19) United States
(12) Patent Application Publication
(10) Pub. No.: US 2013/0206318 A1
(43) Pub. Date: Aug. 15, 2013

(54) REPAIR OF DELAMINATED PLATES WITH PIEZOELECTRIC MATERIALS

(71) Applicants: Quan Wang, Winnipeg (CA); Nan Wu, Winnipeg (CA)

(72) Inventors: Quan Wang, Winnipeg (CA); Nan Wu, Winnipeg (CA)

(73) Assignee: Technology Transfer Office, University of Manitoba, Winnipeg (CA)

(21) Appl. No.: 13/817,250

(22) PCT Filed: Aug. 19, 2011
(86) PCT No.: PCT/CA11/50510

§ 371 Date: Apr. 26, 2013

Related U.S. Application Data
(60) Provisional application No. 61/401,902, filed on Aug. 19, 2010.

(51) Int. Cl. B32B 43/00; H01L 41/08; H01L 41/09

(52) U.S. Cl. CPC B32B 43/00; H01L 41/09; H01L 41/08
USPC 156/64; 318/116; 310/365

(57) ABSTRACT

A piezoelectric patch can be used to repair a defective structure having a plate configuration. The piezoelectric patch can be energized with an applied voltage that is configured to sustain the loading arising from the plate. The applied voltages and electrodes of the patch can be configured based on a numerical model and a finite element method (FEM).

### CLAIM OF PRIORITY

This patent application claims the benefit of priority, under 35 U.S.C. Section 119(e), to Quan Wang et al., U.S. Provisional Patent Application Ser. No. 61/401,902, entitled “REPAIR OF DELAMINATED PLATES WITH PIEZOELECTRIC MATERIALS,” filed on Aug. 19, 2010 (Attorney Docket No. 3035.003PRV), which is hereby incorporated by reference herein in its entirety.

### BACKGROUND

Damage which occurs during service is usually inevitable in aerospace, aeronautical, mechanical, civil and offshore structures. Such damage, when left unrepaired, can deteriorate rapidly due to the singularity of the stress and strain in the immediate vicinity of the affected area.

A crack or delamination can be repaired by attaching a reinforcement plate to the damaged area to the host structure. However, this is often inadequate because loading can change over time and the reinforcement may be unsuitable for stresses arising under a different load.

### OVERVIEW

Piezoelectric patches can be used to repair a delaminated plate (for example, square or rectangular) under a static transverse loading. Discrete electrodes mounted on a piezoelectric patch can be employed to eliminate the shear stress singularity along the delamination edges with the piezoelectric effect. A numerical model can be used to select the voltages applied to individual electrodes of a piezoelectric patch. The voltages are configured to reduce the stress singularity along delamination edges as a whole. A finite element model can be used to verify the numerical model and the repair methodology. Numerical simulations indicate that larger voltages applied to the discrete electrodes are suitable for shorter delamination. The voltages increase when the delamination is close to the mid-face of the host plate.

In one example, a piezoelectric patch can be used to repair a cantilevered beam. The cantilevered beam can have damage in the form of a notch or a crack.

The various examples described herein can be combined in any permutation or combination. This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A, 1B, and 1C illustrate views of a delaminated plate structure.

FIGS. 2A, 2B, and 2C illustrate a finite element model of a delaminated plate, distributed electrodes, and meshing result.

FIG. 3 illustrates a graph of tensile stress distributions and the voltages on edge 1 of the lower layer of a square delamination at the center of a plate (L1=L2=0.1 m, a=b=0.1 m, t=0.005 m).

FIGS. 4A, 4B, and 4C illustrate FEM simulation of shear stress distributions along delamination edges with different voltages (L1=L2=0.1 m, a=b=0.1 m, t=0.005 m).

FIG. 5 illustrates a graph of shear stress distributions along edge 1 of a square delamination (L1=L2=0.1 m, a=b=0.1 m, t=0.005 m).

FIG. 6 illustrates a graph of shear stress distributions along edge 2 of a square delamination eccentrically located at the plate (L1=0.175 m, L2=0.1125 m, a=b=0.075 m, t=0.005 m).

FIG. 7 illustrates a graph of shear stress distributions along edge 2 of a rectangular delamination at the center of the plate (L1=0.05 m, L2=0.1 m, a=0.2 m, b=0.1 m, t=0.005 m).

FIG. 8 illustrates a graph of variation of the voltage versus the length of a delamination (L1=L2=0.1 m, b=0.1 m, t=0.005 m).

FIG. 9 illustrates a graph of variation of voltage versus position of a delamination (L2=0.2 m, a=b=0.05 m, t=0.005 m).

FIG. 10 illustrates variation of voltage versus thickness of the upper layer of a delamination (L1=L2=0.1 m, a=b=0.1 m).

FIG. 11 illustrates a system according to one example.

FIG. 12 illustrates a method according to one example.

FIG. 13 illustrates a notched cantilever beam bonded with a piezoelectric layer subjected to a dynamic loading, according to one example.

FIG. 14 illustrates variation of the largest slope discontinuity at the notch position during vibration versus the repair coefficient, according to one example.

FIGS. 15A and 15B illustrate Von Mises stress distribution at the notch position of vibrating cantilever beam, according to one example.

FIG. 16A illustrates a notched beam and piezoelectric layer, according to one example.

FIG. 16B illustrates piezoelectric sensors and an actuator bonded above the notch area, according to one example.

FIG. 17 illustrates an experimental set-up, according to one example.

FIG. 18 illustrates a comparison of repair effect versus gain factors, according to one example.

### DETAILED DESCRIPTION

Tensile and compressive forces are distributed on the upper and lower layers of a delamination. The forces can lead to a shear stress singularity and a corresponding second fracture mode on the delamination edges.

The delaminated plate can be repaired by eliminating the tensile and compressive forces along the edges of delamination layers using piezoelectric patches. A configuration of discrete electrodes on the patches and the voltages applied to those electrodes can be determined by a numerical model and verified by FEM. Variables can include the size and location of the delamination area and the voltages applied to the various discrete electrodes.

### Introduction

A piezoelectric material exhibits reciprocal electrical-mechanical energy transforming characteristics. Based on the electro-mechanical effect of piezoelectric materials, a voltage can be applied to generate forces on repaired structures so that the repair is dynamic in that the forces change when the damaged condition changes or when the external loading changes.

A cracked beam structure or column structure can be repaired using a piezoelectric patch. A beam or a column subjected to vertical or axial forces, can be repaired using boundary conditions and a numerical model.

For composite materials, delamination can be repaired using piezoelectric patches under a static loading using a finite element model (FEM). A closed-loop feedback control repair can be used for a vibrating delaminated beam structure using piezoelectric patches. Both the numerical model and FEM can be used to analyze the repair effect.

The present subject matter provides for the repair of a delaminated plate under a static loading via piezoelectric patches. A repair method using discrete electrodes mounted on the surfaces of the piezoelectric patches is described. FEM is used to verify the effectiveness of the disclosed repair methodology.

### I. Numerical Model for Repair of a Delaminated Plate Via Piezoelectric Patches

A) Stress Analysis of a Delaminated Plate

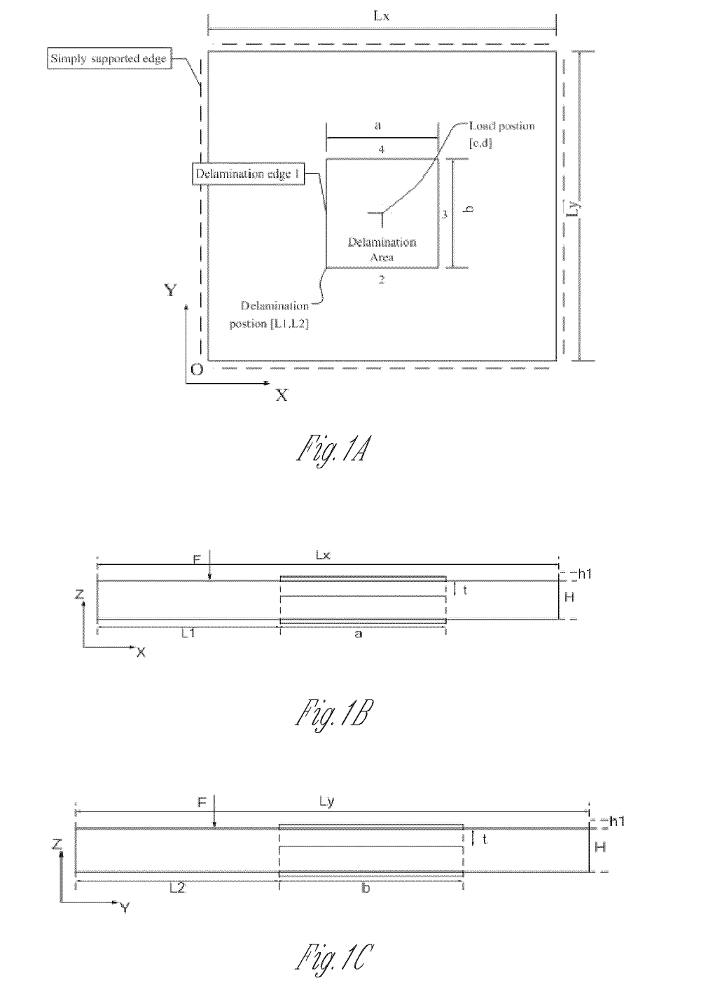

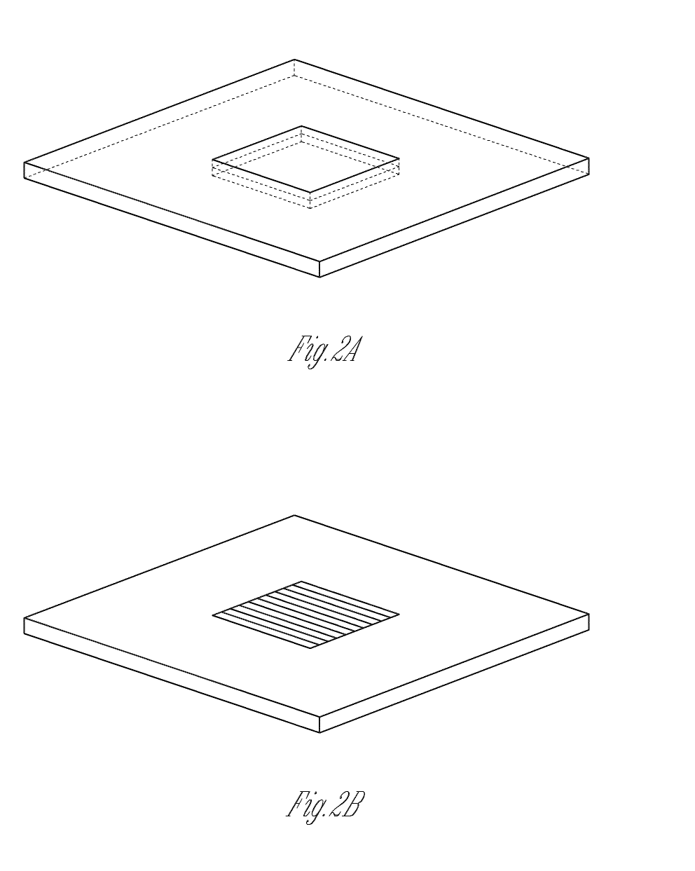

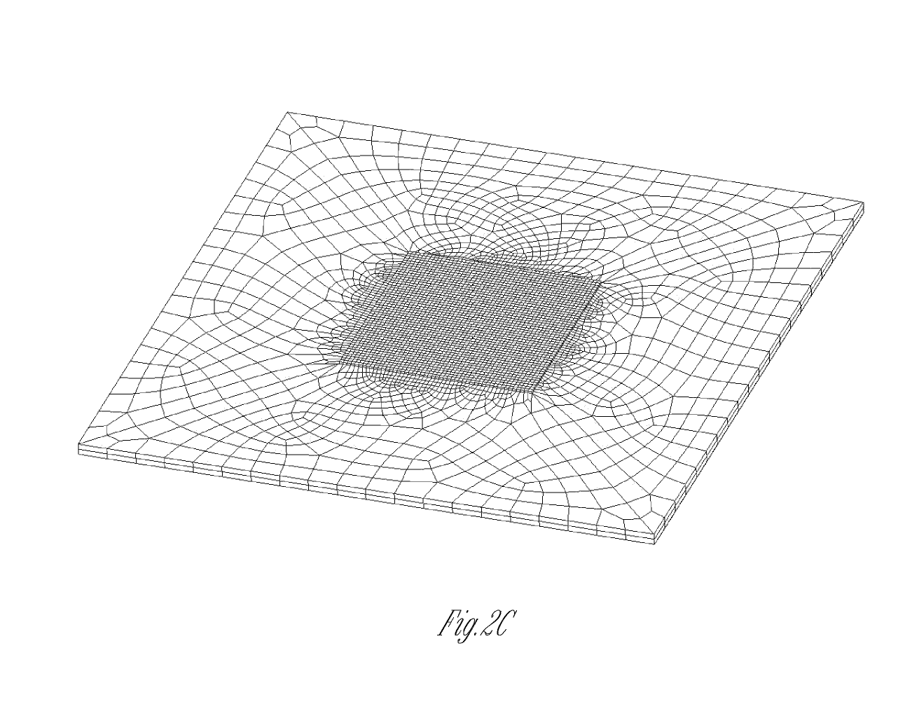

A delaminated square plate subjected to a static loading is shown in FIG. 1. Consider a single rectangular delamination. Delamination edge numbering is illustrated by FIG. 1A. FIGS. 1B and 1C illustrate the cross sections of the delaminated area within XZ and YZ planes, respectively. Piezoelectric patches are surface bonded on the delaminated area. Lx and Ly are the length and width of the delaminated plate (for square plate Lx=Ly); H and t are the thicknesses of the host plate and the upper layer of the delamination, respectively; a and b are the lengths of the delamination edges along X- and Y-directions, respectively; h₁ is the thickness of piezoelectric patches. Point O is the coordinate origin in XY plane; L1 and L2 indicate the distances of the left lower corner of the delamination from the coordinate origin along X- and Y-directions, respectively. F is a vertical static load applied to the surface of the delaminated plate.

While a vertical load is applied to the host plate, deflection will take place along the delaminated area. Axial elongation and compression along X- and Y-directions of the two delaminated layers will be induced accordingly due to the bending of the host structure. Because of the tensile and compressive forces induced, shear stress singularity would be initiated at crack joints of the upper and lower layers of the delamination leading to a second fracture mode according to fracture mechanics. Given the induced stress concentration on the delamination edges, piezoelectric patches can be used to produce shear forces between the piezoelectric patches and the host delaminated plate by applying voltages to decrease the magnitude of tensile and compressive forces on the upper and lower delamination layers and hence the shear stress singularity can be erased accordingly.

To find the voltages to apply to the piezoelectric patches, the tensile and compressive forces on the delamination layers generated by the bending of the host plate is estimated. Assume that the compressive force Pₓᵤ (P_{yu}) and tensile force Pₓᵤ (P_{yu}) along X- (Y-) direction are induced on the upper and lower layers of the delamination. Based on classical elastic plate theory, compression and elongation displacements of the central axis of upper and lower delamination layers along X-direction, Δuᵤ and Δuₗ, can be expressed as follows:

$$\begin{matrix}{Δ {u}_{u} = \frac{1}{2} ( H - t ) ( \frac{\partial {w}_{r} ( x , y )}{\partial x} {{\vert}_{x = L 1 + a , y} - \frac{\partial {w}_{i} ( x , y )}{\partial x} \vert}_{x = L 1 , y} ) , \\ Δ {u}_{1} = \frac{t}{2} {( \frac{\partial {w}_{l} ( x , y )}{\partial x} \vert}_{x = L 1 , y} - \frac{\partial {w}_{r} ( x , y )}{\partial x} \vert}_{x = L 1 + a , y} ) & ( 1 ) \\ {Δ {u}_{l} = \frac{t}{2} {( \frac{\partial {w}_{1} ( x , y )}{\partial x} \vert}_{x = L 1 , y} - \frac{\partial {w}_{t} ( x , y )}{\partial x} \vert}_{x = L 1 + a , y} ) , & ( 2 )\end{matrix}$$

where wᵣ(x,y)|_{x=L1+a,y} wᵣ(x,y) and wₗ(x,y) are the deflections on edges 1 and 3 in FIG. 1A. Following the same idea, compression and elongation displacements of the central axis of upper and lower delamination layers along Y-direction, Δvᵤ and Δvₗ, can be expressed as:

$$\begin{matrix}{{Δ {u}_{u} = \frac{1}{2} ( H - t ) {( \frac{\partial {w}_{r} ( x , y )}{\partial x} \vert}_{x , y = L 1 + a , y} - \frac{\partial {w}_{l} ( x , y )}{\partial x} \vert}_{x = L 1 , y} ) , \\ Δ {v}_{1} = \frac{t}{2} {( \frac{\partial {w}_{l} ( x , y )}{\partial y} \vert}_{x , y = L 2} - \frac{\partial {w}_{r} ( x , y )}{\partial y} \vert}_{x , y = L 2 + b} ) & ( 3 ) \\ {Δ {u}_{l} = \frac{t}{2} {( \frac{\partial {w}_{l} ( x , y )}{\partial x} \vert}_{x = L 1 , y} - \frac{\partial {w}_{r} ( x , y )}{\partial x} \vert}_{x = L 1 + a , y} ) , & ( 4 )\end{matrix}$$

where wᵣ(x,y)|_{x,y=L1} and wₗ(x,y)|_{x,y=L2+b} are the deflections on edges 2 and 4 in FIG. 1A.

The material of the host plate is assumed to be isotropic. On the delamination area, the tensile and compressive forces of incremental strips along X-direction on upper and lower delamination layers, whose position is denoted by y, with a length of ‘a’ and a width of ‘dy’ can be defined as dPₓᵤ(y) and dPₓₗ(y), respectively, and given as follows:

$$\begin{matrix}{dP}_{xu} ( y ) = ( \frac{Δ {u}_{u} Et}{a} + \frac{υ {P}_{yu}}{a} ) dy \\ {dP}_{xu} ( y ) = ( \frac{Δ {u}_{u} Et}{a} + \frac{υ {P}_{yu}}{a} ) dy , & ( 5 a ) \\ {dP}_{xl} ( y ) = ( \frac{Δ {u}_{l} E ( H - t )}{a} + \frac{υ {P}_{yl}}{a} ) dy \\ {dP}_{xl} ( y ) = ( \frac{Δ {u}_{l} E ( H - t )}{a} + \frac{υ {P}_{yl}}{a} ) dy , & ( 5 b )\end{matrix}$$

where E is Young's modulus of the host plate and υ is Poisson ratio.

The total compressive force Pₓᵤ and tensile force Pₓₗ of the delamination along X-direction can thus be determined using:

$$\begin{matrix}{P}_{xu} = {\int }_{L 2}^{L 2 + b} ( \frac{Δ {u}_{u} Et}{a} + \frac{υ {P}_{yu}}{a} ) d y \\ {P}_{xu} = {\int }_{L 2}^{L 2 + b} ( \frac{Δ {u}_{u} Et}{a} + \frac{υ {P}_{yu}}{a} ) d y , & ( 6 ) \\ {P}_{xl} = {\int }_{L 2}^{L 2 + b} ( \frac{Δ {u}_{l} E ( H - t )}{a} + \frac{υ {P}_{yl}}{a} ) d y \\ {P}_{xl} = {\int }_{L 2}^{L 2 + b} ( \frac{Δ {u}_{l} E ( H - t )}{a} + \frac{υ {P}_{yl}}{a} ) d y . & ( 7 )\end{matrix}$$

Following the same procedure, the total compressive force P_{yu} and tensile force P_{yl} along Y direction could be expressed as:

$$\begin{matrix}{P}_{yu} = {\int }_{L 1}^{L 1 + a} ( \frac{Δ {v}_{u} Et}{b} + \frac{υ {P}_{xu}}{b} ) d x \\ {P}_{yu} = {\int }_{L 1}^{L 1 + a} ( \frac{Δ {v}_{u} Et}{b} + \frac{υ {P}_{xu}}{b} ) d x , & ( 8 ) \\ {P}_{yl} = {\int }_{L 1}^{L 1 + a} ( \frac{Δ {v}_{l} E ( H - t )}{b} + \frac{υ {P}_{xl}}{b} ) d y \\ {P}_{yl} = {\int }_{L 1}^{L 1 + a} ( \frac{Δ {v}_{l} E ( H - t )}{b} + \frac{υ {P}_{xl}}{b} ) d y . & ( 9 )\end{matrix}$$

The above equations provide total tensile and compressive forces on the upper and lower delamination layers.

Consider next, determining the force distribution along the upper and lower delamination layers for the purpose of repair. In order to do so, the delamination layers are discretized into M and N fictitious strips along X and Y directions to describe the compressive and tensile force distributions on the upper and lower delamination layers, respectively. The compressive forces P_{yu}^{f} and Pₓᵤ^{t} and tensile force P_{yt}^{f} and Pₓₜ^{t} on the fictitious strips can be expressed from equations (6˜9) as follows:

$$\begin{matrix}{P}_{yu}^{j} = {\int }_{L 1 + a ( j - 1 ) / M}^{L 1 + aj / M} ( \frac{Δ {v}_{u} Et}{b} + \frac{υ {\sum }_{i = 1}^{N} {P}_{xu}^{i}}{b} ) d x \\ {P}_{yu}^{j} = {\int }_{L 1 + a ( i - 1 ) / 10}^{L 1 + \text{?} / 10} ( \frac{Δ {v}_{u} Et}{b} + \frac{\text{?} {\sum }_{i = 1}^{\text{?}} {P}_{xu}^{i}}{b} ) d x , & ( 10 ) \\ {P}_{yl}^{j} = {\int }_{L 1 + a ( j - 1 ) / M}^{L 1 + aj / M} ( \frac{Δ {v}_{l} E ( H - t ) }{b} + \frac{υ {\sum }_{i = 1}^{N} {P}_{xl}^{i}}{b} ) d x \\ {P}_{yl}^{j} = {\int }_{L 1 + a ( \text{?} - 1 ) / 10}^{L 1 + a \text{?} / 10} ( \frac{Δ {v}_{l} E ( H - t ) }{b} + \frac{υ {\sum }_{i = 1}^{10} {P}_{xl}^{i}}{b} ) d x . & ( 11 ) \\ {P}_{xu}^{i} = {\int }_{L 2 + b ( i - 1 ) / N}^{L 2 + bi / N} ( \frac{Δ {u}_{u} Et}{a} + \frac{υ {\sum }_{i = 1}^{M} {P}_{yu}^{j}}{a} ) d y \\ {P}_{xu}^{i} = {\int }_{L 2 + b ( i - 1 ) / 10}^{L 2 + bi / 10} ( \frac{Δ {u}_{u} Et}{a} + \frac{υ {\sum }_{j = 1}^{10} {P}_{yu}^{i}}{a} ) d y , & ( 12 ) \\ {P}_{xl}^{i} = {\int }_{L 2 + a ( i - 1 ) / N}^{L 2 + bi / N} ( \frac{Δ {v}_{l} E ( H - t ) }{b} + \frac{υ {\sum }_{i = 1}^{N} {P}_{xl}^{i}}{b} ) d y \\ {P}_{xl}^{i} = {\int }_{L 2 + b ( i - 1 ) / 10}^{L 2 + bi / 10} ( \frac{Δ {v}_{l} E ( H - t ) }{\text{?}} + \frac{υ {\sum }_{j = 1}^{N} {P}_{xl}^{i}}{\text{?}} ) d y , \\ \text{?} \text{indicates text missing or illegible when filed} & ( 13 )\end{matrix}$$

where j and i (1<=j<=M, 1<=i<=N) are used to number the discrete sections on the delamination area, distributed along X and Y direction respectively, counting from the left lower corner of the delamination area (coordinate (L1, L2)).

To solve the linear equations (10˜13), the plate deflection w under a static loading is determined. When a transverse load is applied to the surface of the plate, the effect of the delamination on the deflection solution is postulated to be negligible. The deflection of a simply supported rectangular plate under a point load is given as:

$$w ( x , y ) = \frac{4 F}{{π}^{4} DLxLy} {\sum }_{m = 1}^{∞} {\sum }_{n = 1}^{∞} \frac{sin \frac{m π c}{Lx} sin \frac{n π d}{Ly} sin \frac{m π x}{Lx} sin \frac{n π y}{Ly}}{{( {( \frac{m}{Lx} )}^{2} + {( \frac{n}{Ly} )}^{2} )}^{2}} \\ w ( x , y ) = {\sum }_{m = 1}^{∞} {\sum }_{n = 1}^{∞} \frac{sin \frac{m π c}{Lx} sin \frac{n π d}{Ly} sin \frac{m π x}{Lx} sin \frac{n π y}{Ly}}{{( {( \frac{m}{Lx} )}^{2} + {( \frac{n}{Ly} )}^{2} )}^{2}} , \qquad ( 14 )$$

where the bending rigidity of the plate is given as

$$D = \frac{{EH}^{3}}{12 ( 1 - {υ}^{2} )} .$$

By submitting equation (14) into equations (1˜4) and equations (10˜13), the force distributions along upper and lower delamination edges, P_{yu}^{j}Pₓᵤⁱ (PₓᵤⁱP_{yu}^{j}) and P_{yl}^{j}Pₓₗⁱ(PₓₗⁱP_{yl}^{j}), can be expressed as:

$$\begin{matrix}- {P}_{yu}^{j} = {P}_{yl}^{j} = {\sum }_{m = 1}^{∞} {\sum }_{n = 1}^{∞} B ( m , n , j ) + \frac{υ a}{Nb} {\sum }_{i = 1}^{N} {P}_{xu}^{i} \\ {P}_{yu}^{j} = {P}_{yl}^{j} = {\sum }_{m = 1}^{∞} {\sum }_{n = 1}^{∞} B ( m , n , j ) + \frac{\text{?} a}{10 b} {\sum }_{i = 1}^{10} {P}_{xu}^{i} & ( 15 ) \\ {P}_{xl}^{i} {P}_{xu}^{i} = {P}_{xl}^{i} = {\sum }_{m = 1}^{∞} {\sum }_{n = 1}^{∞} A ( m , n , i ) + \frac{\text{?} b}{10 a} {\sum }_{j = 1}^{10} {P}_{yu}^{j} , \\ \text{?} \text{indicates text missing or illegible when filed} & ( 16 )\end{matrix}$$

where A(m, n, i) and B(m, n, j) are given as follow:

$$A ( m , n , i ) = - \frac{1}{{π}^{4} {D ( {m}^{2} {Ly}^{2} + {n}^{2} {Lx}^{2} )}^{2} na} ( \begin{matrix}2 t ( H - t ) EF \cdot sin \frac{m π c}{Lx} \cdot sin \frac{n π d}{Ly} \cdot \\ {mLx}^{2} {Ly}^{4} ( \begin{matrix}- cos \frac{m π ( L 1 + a )}{Lx} \cdot cos \frac{n π ( NL 2 + bi - b )}{NLy} + \\ cos \frac{m π L 1}{Lx} \cdot cos \frac{n π ( NL 2 + bi - b )}{NLy} + \\ cos \frac{m π ( L 1 + a )}{Lx} \cdot cos \frac{n π ( NL 2 + bi )}{NLy} - \\ cos \frac{m π L 1}{Lx} \cdot cos \frac{n π ( NL 2 + bi )}{NLy}\end{matrix} )\end{matrix} )$$

$$B ( m , n , j ) = - \frac{1}{{π}^{4} {D ( {m}^{2} {Ly}^{2} + {n}^{2} {Lx}^{2} )}^{2} mb} ( \begin{matrix}2 t ( H - t ) EF \cdot sin \frac{m π c}{Lx} \cdot sin \frac{n π d}{Ly} \cdot \\ {nLx}^{4} {Ly}^{2} ( \begin{matrix}cos \frac{n π ( L 2 + b )}{Ly} \cdot cos \frac{m π ( ML 1 + aj - b )}{MLx} - \\ cos \frac{m π L 2}{Ly} \cdot cos \frac{m π ( ML 1 + aj - a )}{MLx} - \\ cos \frac{n π ( L 2 + b )}{Ly} \cdot cos \frac{m π ( ML 1 + aj )}{MLx} + \\ cos \frac{n π L 2}{Ly} \cdot cos \frac{n π ( ML 1 + aj )}{MLx}\end{matrix} )\end{matrix} )$$

$$D = \frac{4 P}{12 ( 1 - \text{?} )} , \\ \text{?} \text{indicates text missing or illegible when filed}$$

By solving the (M+N)-linear equations (15) and (16), the force distributions along the delamination edges, P_{yu}^{j}Pₓᵤⁱ(PₓᵤⁱP_{yu}^{f}) and P_{yl}^{j}Pₓₗⁱ(PₓₗⁱP_{yl}^{j}), can be solved.

B) Repair of Delaminated Plates using Piezoelectric Patches

Discrete electrodes can be used for repairing delaminated plates. The discrete electrodes can be configured on the positions of fictitious strips distributed along two parallel edges, on which the largest shear stress occurs in order to eliminate the shear stress singularity on the two edges. Numerical simulations show that stress singularity on the other two edges are reduced as well based on the design of discrete electrodes.

From the solution for tensile and compressive forces distributed on the delamination layers, voltages on these electrodes can be applied to generate shear forces between the host plate and piezoelectric patches so that the distributed tensile and compressive forces on the delamination layers can be reduced as a whole. The shear forces on delamination edges at crack joints of the upper and lower delamination layers are thus reduced at the same time so that the slide mode fracture can be controlled.

Because of the discrete electrodes design, piezoelectric patches bonded above the delamination area are separated into M (N) sections along X- (Y-) direction and any individual piezoelectric section can thus be assumed to be a thin bar.

Piezoelectric patches are polarized by Z-direction. The expression of the shear force between a metal substrate and a piezoelectric patch (assuming a complete bonding between them) is given by:

$$S = \frac{EHT}{ψ + α} Λ , \qquad ( 17 )$$

where ψ=EH/Eₚh₁, α=6 when a bending bar is considered and Λ=d₃₁V/h₁. h₁ is the thickness of the piezoelectric patch, d₃₁ is the piezoelectric charge coefficient, Eₚ is the equivalent Young's modulus of the piezoelectric patch, T is the width of distributed electrodes on the piezoelectric patch

$$( T = \frac{a}{M} / \frac{b}{N} )$$

and V is the input voltage, V=Vⱼ when an electric potential is applied to the jth electrode.

Shear forces induced by the applied voltage on jth/ith electrode between the piezoelectric patches and the host plate can be given by:

$$\begin{matrix}{S}_{y}^{j} = \frac{EHa / M}{ψ + 6} \cdot \frac{{d}_{31} {V}_{j}}{{h}_{1}} . \\ {S}_{yu}^{\text{?}} = \frac{\text{?}}{10} = \frac{\text{?}}{10} . & ( 18 ) \\ {S}_{x}^{i} = \frac{EHb / N}{ψ + 6} \cdot \frac{{d}_{31} {V}_{i}}{{h}_{1}} \\ {S}_{yu}^{\text{?}} = \frac{\text{?}}{10} = \frac{\text{?}}{10} , \\ \text{?} \text{indicates text missing or illegible when filed} & ( 19 )\end{matrix}$$

S_{y}^{j} (Sₓⁱ) can be used as the repair forces to erase the tensile and compressive forces on the upper and lower delamination layers along Y- (X-) direction Pₓᵤⁱ/P_{yu}^{j}. The repair strategy entails applying repair forces, induced by piezoelectric patches, with the same magnitude but in the opposite sign with the calculated tensile/compressive force distributions along the edges, i.e. S_{y}^{j}=−P_{yu}^{j}=P_{yl}^{j} (Sₓⁱ=−Pₓᵤⁱ=Pₓₗⁱ). The voltages are thus obtained by:

$$\begin{matrix}{V}_{j} = \frac{( {\sum }_{m = 1}^{∞} {\sum }_{n = 1}^{∞} B ( m , n , i ) + \frac{υ a}{Nb} {\sum }_{i = 1}^{N} {P}_{xu}^{i} ) \cdot ( ψ + 6 ) \cdot {h}_{1} \cdot M}{{EHad}_{31}} \\ {S}_{yu}^{\text{?}} = - {S}_{yl}^{\text{?}} = - {P}_{yu}^{j} = \frac{\text{?}}{10} = - {\sum }_{m = 1}^{∞} {\sum }_{n = 1}^{∞} B ( m , n , j ) + \frac{\text{?}}{10 b} {\sum }_{\text{?} = 1}^{10} {P}_{xu}^{i} . & ( 20 ) \\ {V}_{i} = \frac{( {\sum }_{m = 1}^{∞} {\sum }_{n = 1}^{∞} A ( m , n , i ) + \frac{υ b}{Ma} {\sum }_{j = 1}^{M} {P}_{yu}^{i} ) \cdot ( ψ + 6 ) \cdot {h}_{1} \cdot N}{{EHbd}_{31}} \\ {S}_{xu}^{\text{?}} = - {S}_{xl}^{\text{?}} = - {P}_{xu}^{i} = \frac{\text{?}}{10} = - {\sum }_{m = 1}^{∞} {\sum }_{n = 1}^{∞} A ( m , n , j ) + \frac{\text{?}}{10 a} {\sum }_{\text{?} = 1}^{10} {P}_{xu}^{j} . \\ \text{?} \text{indicates text missing or illegible when filed} & ( 21 )\end{matrix}$$

### II. Finite Element Model (FEM) of Repair of Delaminated Plates via Piezoelectric Patches

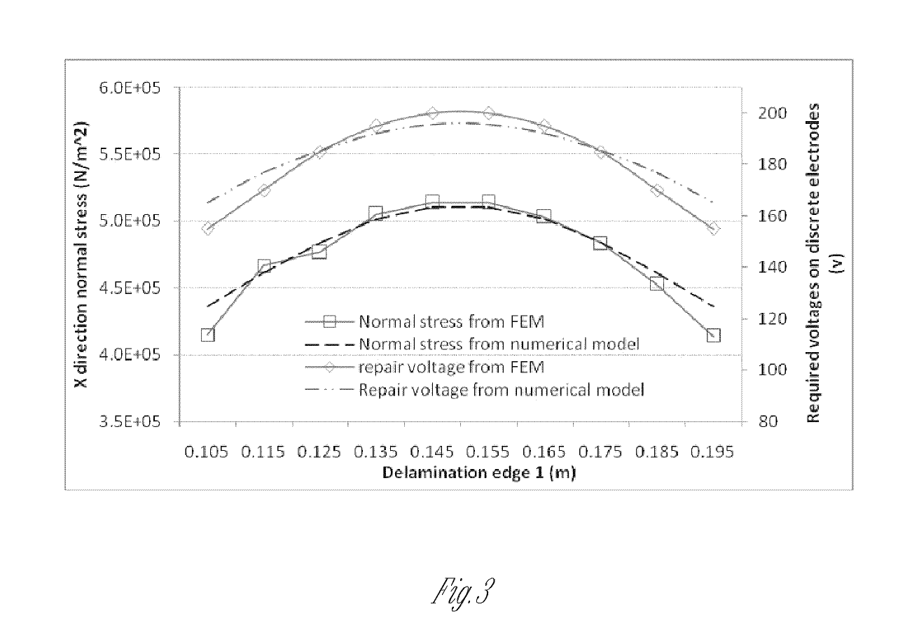

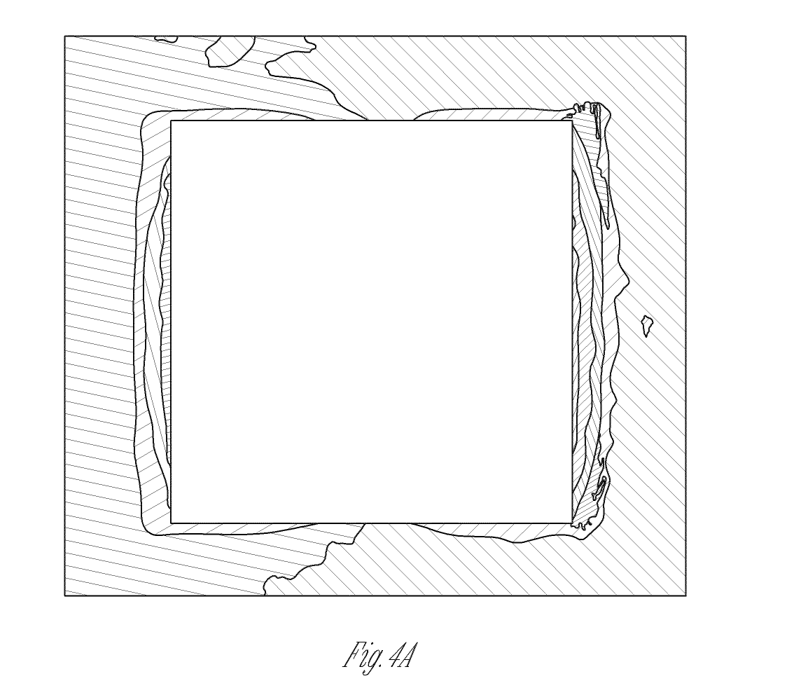

The finite element model of a delaminated plate bonded with piezoelectric patches is illustrated in FIGS. 2A, 2B, and 2C. The discrete electrodes are mounted on the surface of piezoelectric patches as shown in FIG. 2B. Finite element analysis software can be used to verify effectiveness of the numerical model. The solid element and the coupled field element are used to mesh the host plate and piezoelectric patches, respectively. Meshing result of the delaminated plate bonded with piezoelectric patches is shown in FIG. 2C. The mesh size of the delamination area is refined to be 2% of the lengths of corresponding delamination edges.

Two delamination layers are assumed to contact with each other without friction. An area contact pair is built between the two delamination layers to simulate the contact plate delamination. Friction factor is set to be zero.

### III. Numerical Simulations and Discussions

Based on the numerical model and FEM, numerical simulations can be evaluated to analyze the repair of a plate. Consider a delaminated square plate with four simply supported edges subjected to a loading F=100N downwardly applied at its center. The delamination edges on both X and Y directions are discredited into 10 sections (M=N=10) for calculating the tensile and compressive forces distribution. The geometry of the delaminated plate and the material properties are given as follows: Lx=Ly=0.3 m, E=200*10⁹N/m², H=0.01 m, h₁=0.001 m, Ep=65*10⁹N/m², d31=256e-12 C/N.

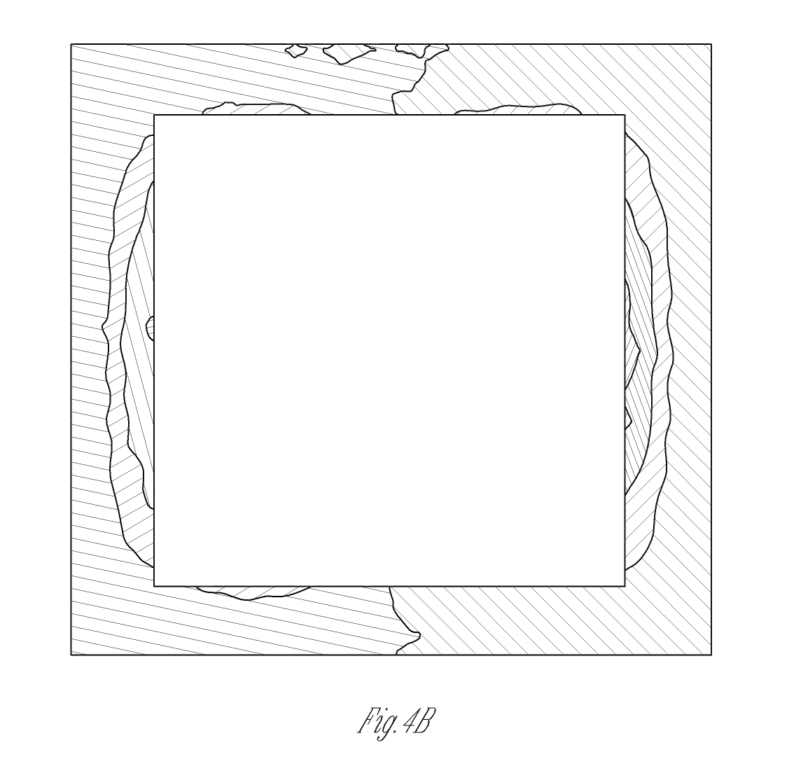

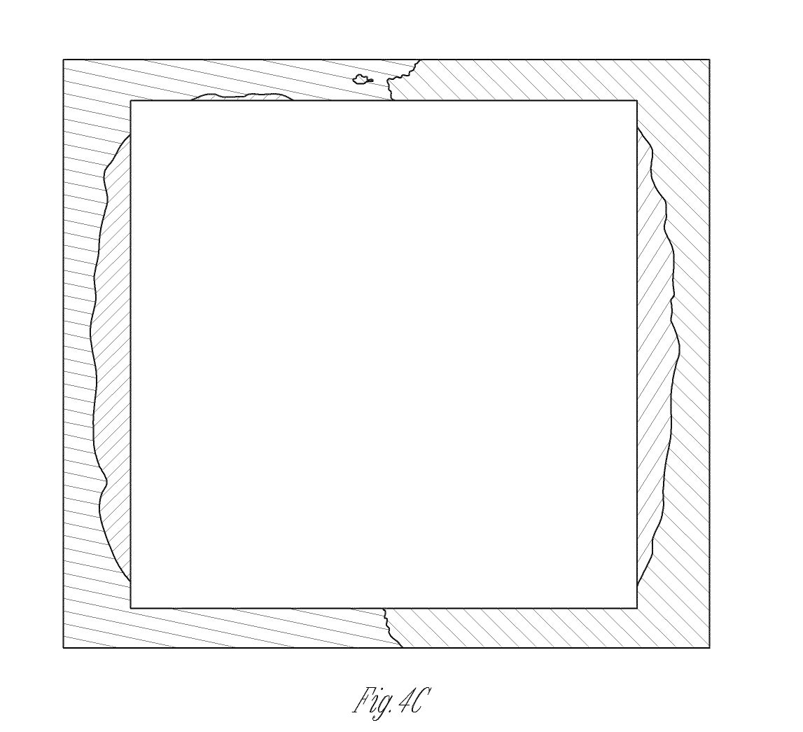

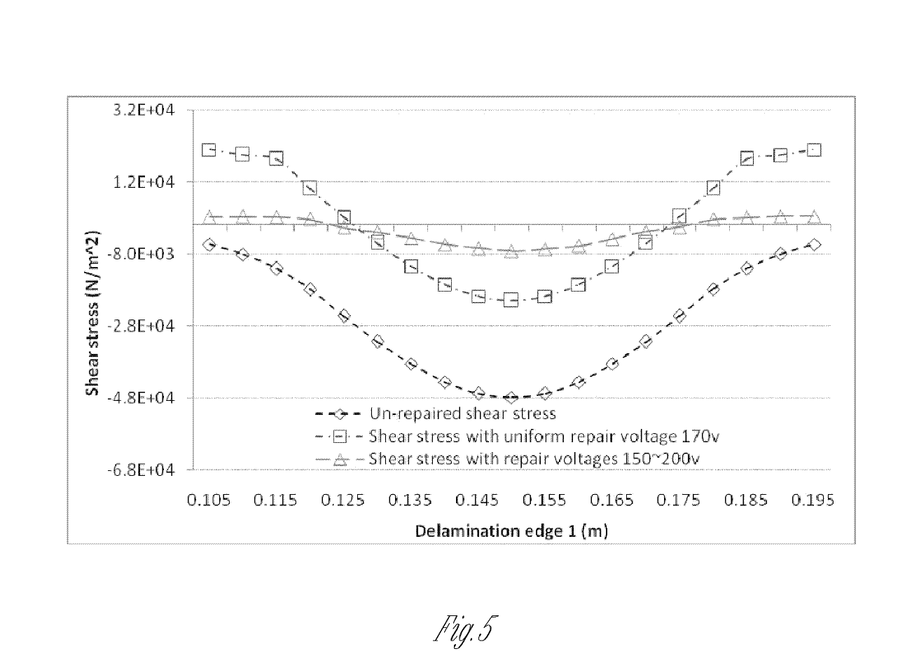

The effectiveness of the numerical model in predicting tensile/compressive force distribution along the delamination layer and voltages applied to the discrete electrodes distributed along Y-direction for reducing the stress concentration along edges 1 and 3 can be verified by FEM for a symmetric delaminated plate (L1=L2=0.1 m, a=b=0.1 m, t=0.005 m), as shown in FIGS. 3 and 4. As the structure is symmetrical in XY plane, only the delamination edge 1 is analyzed. The tensile stress distribution on the lower layer along edge 1 and the voltages applied to the 10 discrete electrodes from both the numerical model and FEM are shown in FIG. 3. The largest stress and voltage differences between the numerical model and FEM are 5.3% and 6%, respectively. The largest errors for both stress and voltage distributions appear at the ends of the edge. FIG. 4 illustrates the shear stress reduction on edges 1 and 3 when different adjusted voltages are applied to the discrete electrodes. The shear stresses are decreased with a suitable voltage. In the figures, the shaded portions denote variations in stress.

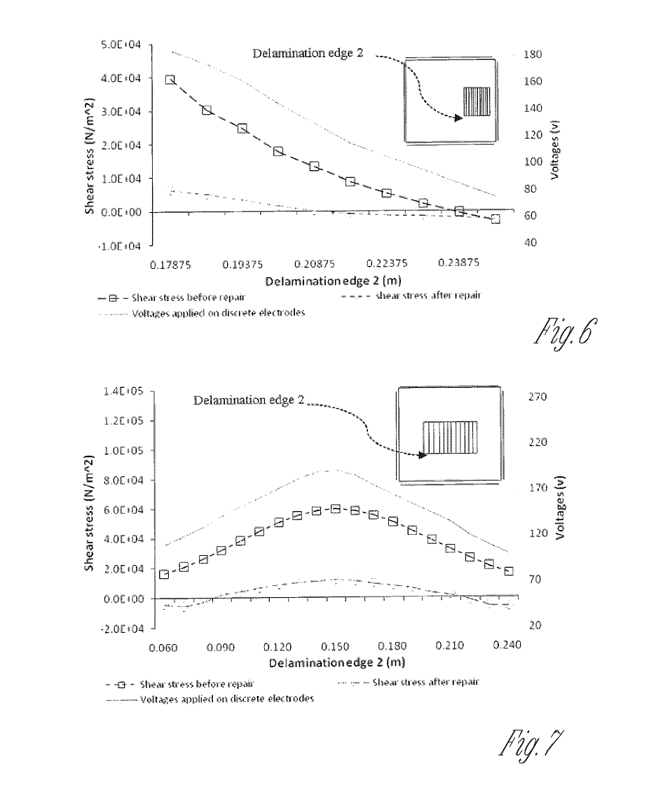

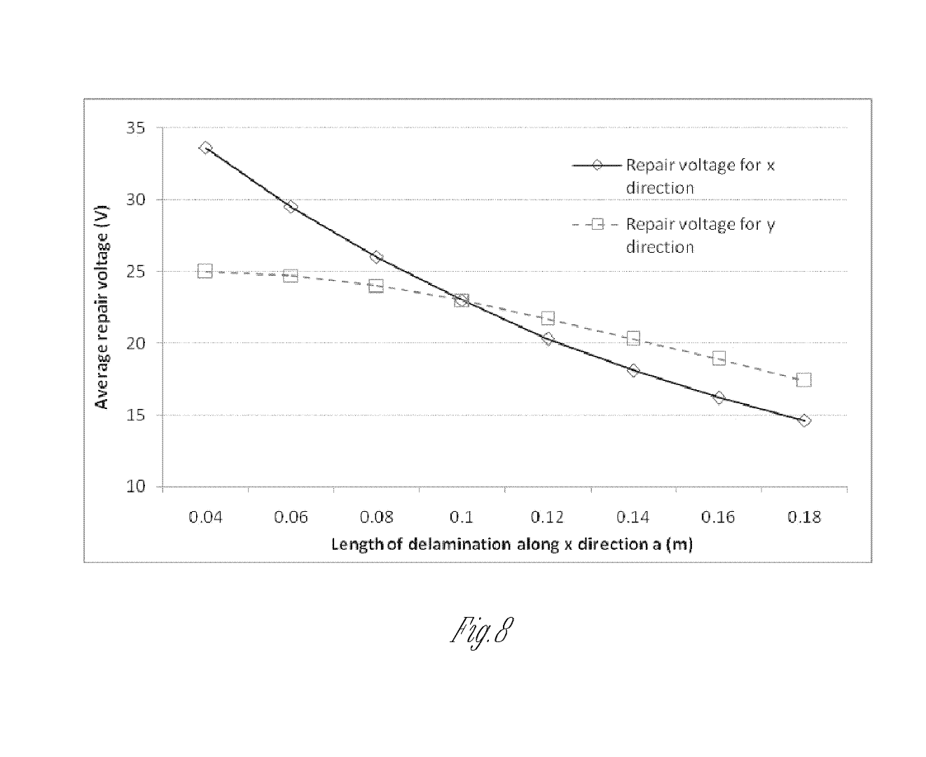

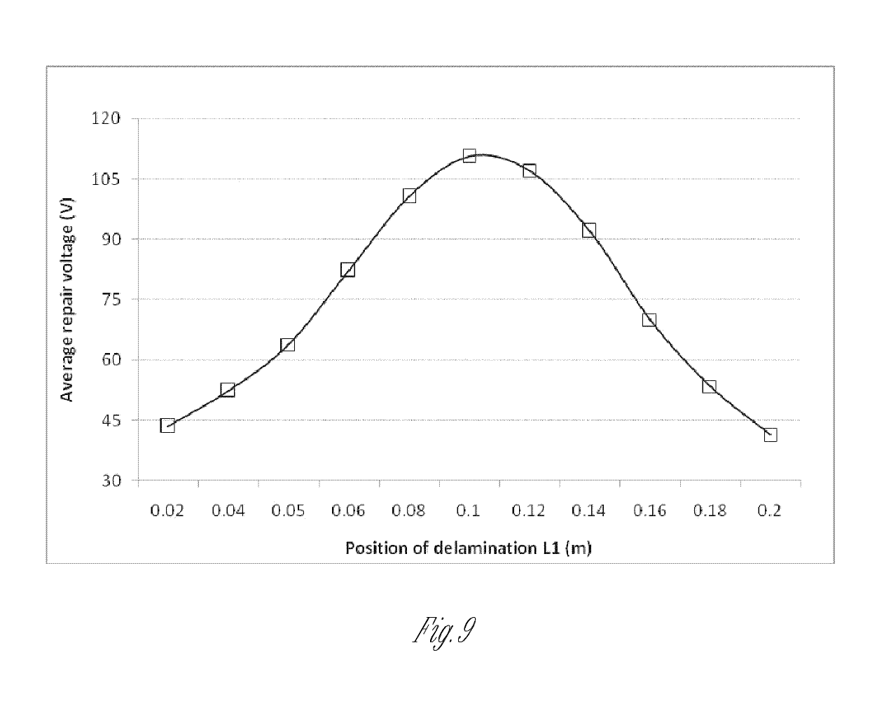

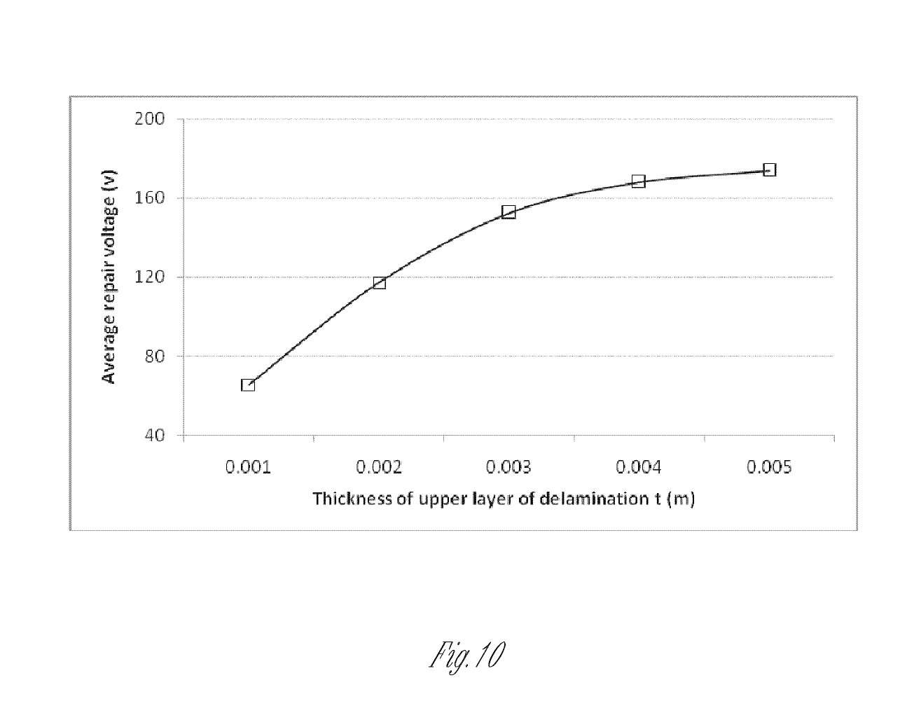

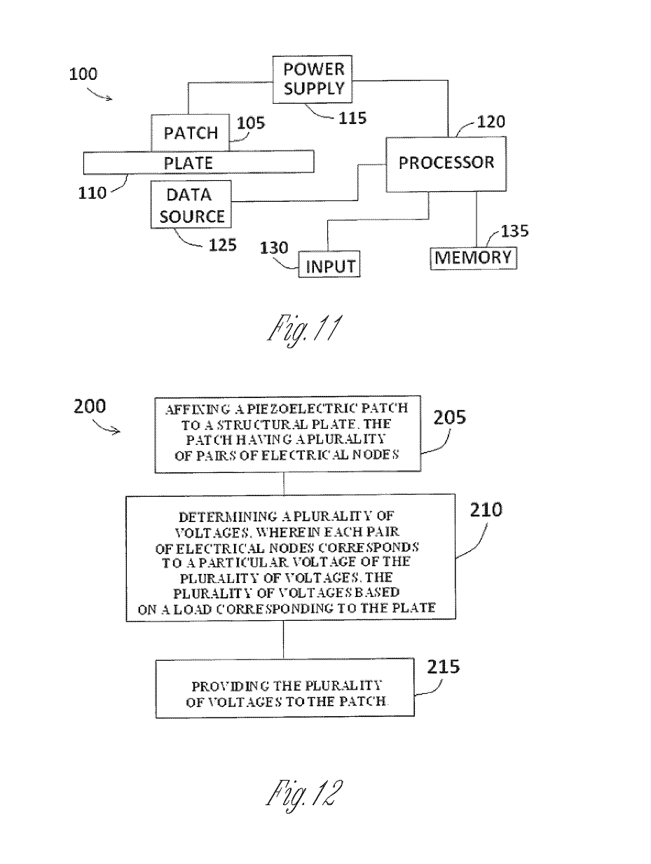

The effectiveness of the discrete electrodes for the delamination repair is further illustrated in FIGS. 5-7 with different delamination sizes and locations. FIG. 5 compares the reduced shear stresses on edge 1 of the delamination by the piezoelectric patches with a single electrode and discrete electrodes for the same structure considered in FIGS. 3-4. As shown, the largest XZ shear stress on edge 1 can be decreased by 85.4% and the lowest shear stress can be decreased by 53.1%, when voltages (Vᵢ,i=1˜10 Vₗ,i=1˜10) are applied to the discrete electrodes. In this example, a 56.4% reduction of the largest shear stress can be achieved when an average voltage (Σᵢ₊₁¹⁰Vᵢ/10Σᵢ₋₁¹⁰Vᵢ/10) is applied to the single electrode. The application of the single electrode, on the other hand, causes an increase in the shear stress on the reverse direction at the ends of delamination edge by 200%, approximately. Thus, the plurality of discrete electrodes provides an efficient repair for the plate delamination while the single patch cannot effectively reduce the shear stress along the delamination edges. The repair effects of discrete electrodes are further shown in FIGS. 6 and 7. For the delaminated plate with a square delamination eccentrically located at L1=0.175 m and L2=0.1125 m, comparison between the YZ shear stress distributions before and after repair along edge 2 is illustrated in FIG. 6. Electrodes are distributed along X-direction aiming to reduce shear stresses on edges 2 and 4, where the largest shear stresses occur. Calculations show that shear stresses along edge 2 are decreased by 84%. On the other hand, on the edge 1, which is parallel to the discrete electrode strips, the largest XZ shear stress is decreased from 18000 N/m² to 10000 N/m². For the delaminated plate with a rectangular delamination (a=0.2 m and b=0.1 m) located at the center of the plate, the reduced shear stresses on edge 2 by the piezoelectric patches with discrete electrodes are shown in FIG. 7. The largest stress is on edges 2 and 4. On edge 2, the largest YZ shear stress is decreased by 83.3% and the lowest shear stress is reduced by 68%. On the other hand, calculations show that the largest shear stress on the edge 3 is also decreased by 50%, approximately.

FIGS. 8-10 illustrate the dependence of the delamination size and location on the average value of the voltages applied to the discrete electrodes. The voltages versus different lengths of delamination are shown in FIG. 8, when L1=L2=0.1 m, b=0.1 m, and t=0.005 m are set. The voltages on electrodes in both X- and Y-directions decrease with the increase of the lengths of edges 2 and 4. This observation can be explained by equations (6˜9). The equations show that tensile and compressive forces generated on upper and lower delamination layers decrease with the increase of the delamination length ‘a’ or ‘b’. The voltage variation versus different positions of delamination along X direction is shown in FIG. 9 with a=b=0.05 m, t=0.005 m and L2=0.2 m. The figure shows voltages on electrodes distributed along X-direction because the largest shear stress is on edges 2 and 4. The voltage reaches the highest value when the delamination is located at the center of the plate. FIG. 10 illustrates the variation of the voltages versus the location of the delamination in the thickness direction given other geometry parameters are fixed to be L1=L2=0.1 m, a=b=0.1 m showing a symmetric structure. The average value of voltages applied to the discrete electrodes increases from 65v to 183v when the delamination is located from t=0.001 m to t=0.005 m (H/2). The voltage increases when the delamination is close to the mid-face of the host plate, which can be seen from equations (20) and (21).

The repair method disclosed herein is applicable to a single delamination in a thin plate made from an isotropic material as indicated earlier. Other plate models, for example, Mindlin-Reissner thick plate theory, can be employed to repair a thick plate structure.

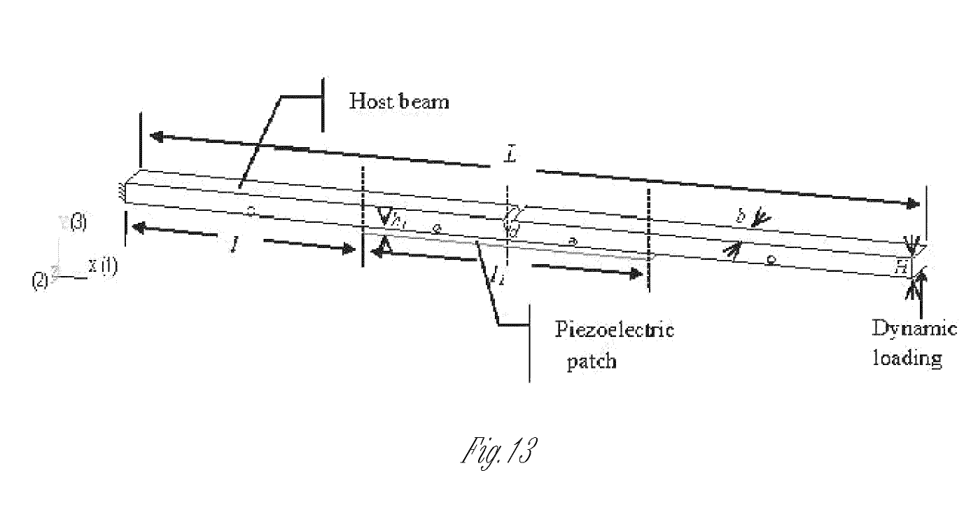

FIG. 11 illustrates system 100 according to one example. System 100 includes patch 105, processor 120, and power supply 115. Patch 105 can include a piezoelectric material having a planar surface configured for affixation to structural plate 110. Patch 105 can include a plurality of segments and each segment includes a pair of electrodes. In one example, the plurality of segments of patch 105 are in parallel alignment. Patch 105 can be rectangular, square, or other configuration. Patch 105 is configured to be affixed at the site of a delamination or other failure of plate 110. In one example, patch 105 includes ten discrete segments. According to one example, each segment is electrically isolated from at least one other segment.

System 100 includes data source 125. Data source 125 is configured to provide data corresponding to plate 110. Data source 125 can includes a model corresponding to loading of plate 110. Data source 125 can include a sensor coupled to plate 125 or coupled to patch 105.

System 100 includes processor 120. Processor 120 is coupled to data source 125 and is configured to execute an algorithm to determine a voltage corresponding to each segment of the plurality of segments of patch 105. The algorithm can be embodied in a set of instructions stored in memory 135. The algorithm can include a numeric model or instructions for implementing a FEM.

Input 130 can include a user operable input, such as a keyboard. Input 130 can be configured to receive a user-generated estimate of a load corresponding to plate 110.

System 100 includes power supply 115. Power supply 115 has a plurality of outputs coupled to the plurality of pairs of electrodes of patch 105.

Processor 120 is configured to provide a signal to modulate the outputs. The outputs can include a modulated voltage, current, frequency, or a phase.

FIG. 12 illustrates method 200 according to one example. In this example, at 205, method 200 includes affixing a piezoelectric patch to a structural plate, the patch having a plurality of pairs of electrical nodes. This can include bonding a contact surface of the patch with the structural plate.

In one example, patch 105 is positioned on one side of a damaged plate. In one example, a first patch 105 is positioned on a first side and a second patch 105 is positioned on a second side in which the first and second sides are opposite one another. Voltages delivered to electrodes of patches on opposing sides of a plate can be the same or different. The voltage can be modulated to compensate for a static load or to compensate for a dynamic load.

At 210, method 200 includes determining a plurality of voltages, wherein each pair of electrical nodes corresponds to a particular voltage of the plurality of voltages, the plurality of voltages based on a load corresponding to the plate. In one example, this can include executing an algorithm using a processor. The algorithm can be based on a numeric model. In one example, determining the voltages can include estimating at least one of a tensile force and a compressive force corresponding to the load. In addition, this can include estimating a force corresponding to each of the pair of electrical nodes or determining a force distribution corresponding to the load. The force distribution can be along a delaminated edge of the plate. Determining voltages can include executing a process based on a finite element model. The location of the patch relative to the location of the delamination of the plate may affect the voltages.

At 215, method 200 includes providing the plurality of voltages to the patch.

The electrodes can be activated by a modulated voltage, a modulated current, a modulated frequency, a modulated duty cycle or any combination of varying energy.

### Notched Beam Repair

An example of the present subject matter is directed to repair of a notched beam subjected to dynamic loading with piezoelectric patches.

A notched cantilever beam structure subjected to dynamic loading can be repaired by a piezoelectric patch.

A piezoelectric patch used as a sensor is placed on the notch position to monitor the severity of the stress concentration around the notch area by measuring the charge output on the sensor. A patch used as an actuator is located around the notch area to generate a bending moment by employing an actuation voltage to reduce the stress concentration at the notch position. The actuation voltage on the actuator is determined from a feedback circuit. An analytical model can determine the actuation voltage and a finite element model (FEM) can be used to verify the analytical model.

Damages such as crack, notch or delamination in aerospace, mechanical, civil and offshore structures due to fatigue, corrosion or accidence during service are usually inevitable. The stress or strain concentration in the vicinity of the damages will lead to structure instability or failure and can be reduced with certain structural repair technologies.

Bonded repair can increase the service life of damaged structures by melding or mounting additional high stiffness patches onto the damaged areas to improve the stability of a host structure. However, such a repair is dependent on the nature of the damage and the external loading. In addition, the bonded patches may induce additional increment of the stress concentration at the damaged part due to a variety of external loadings.

According to one example of the present subject matter, repair of a notched cantilever beam structure subjected to a dynamic loading can be accomplished by using piezoelectric patches based on a feedback strategy. The stress concentration at a notch tip can be decreased by reducing the slope discontinuity at the notched position of the bending beam structure using actuated piezoelectric patches so as to avoid the occurrence of a real notch.

The reduction of the slope discontinuity at the notch position, which directly represents the severity of the stress concentration at the notch tip, is used as the criterion in evaluating the reduction of the stress concentration and identifying an actuation voltage applied to the piezoelectric actuator.

In one example, a notch can be cut on an aluminum alloy beam by a thin grinding wheel. A small piezoelectric patch can be used as a sensor and placed on the notch position to monitor the severity of the stress concentration around the notch area by measuring the charge output on the sensor, and a piezoelectric patch used as an actuator can be located around the notch area to generate the counteracting repair bending moment to decrease the plastic zone around the tip of the notch so that the stress concentration at the notch tip can be controlled. An analytical model for the repair design can explain the repair process and guide the experiments. A FEM strategy can be used for verification purpose.

### Feedback Repair

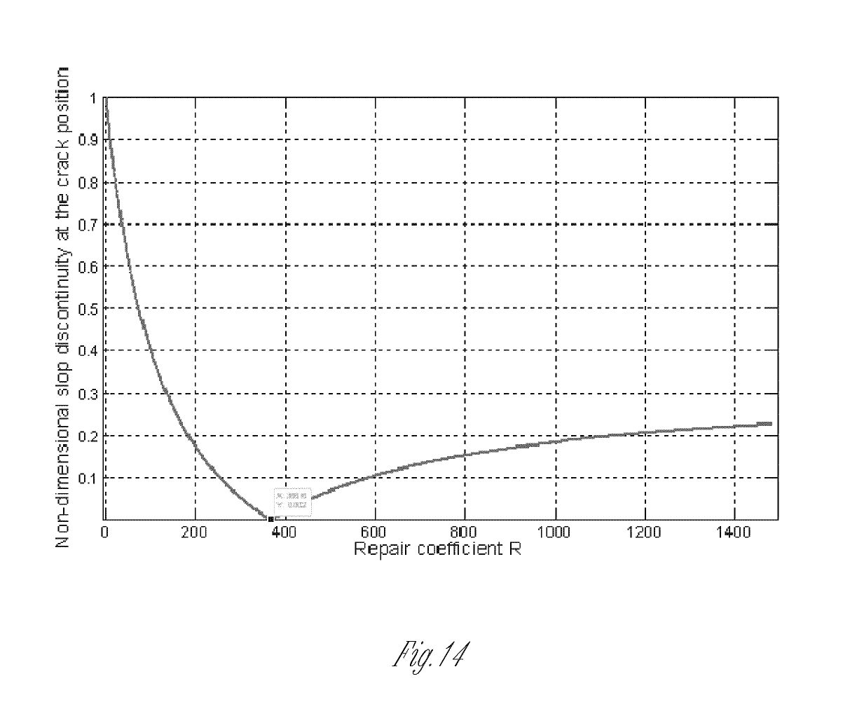

A repair technique is illustrated using a notched cantilever beam subjected to a dynamic loading at its free end. The notched cantilever beam bonded with a piezoelectric layer is shown in FIG. 13. A transverse notch is located at the upper surface of the beam, while the piezoelectric layer is bonded at the bottom of the beam corresponding to the notch area to reduce the stress concentration at the notch tip. L is the total length of the notched beam, while l is the distance from the fixed end of the cantilever beam to the left end of the piezoelectric layer. The length of the piezoelectric layer is l₁, and the notch is located at the central position of the piezoelectric layer. d is the depth of the notch. H and h₁ are thicknesses of the host beam and the piezoelectric layer, respectively. The width of the notched beam is b. A periodical dynamic point force, f(x, t)=F sin(ω′t)δ(x−L), is applied at the feed end of the cantilever beam, where w′ is the angular velocity of the external force and δ(x−L) is the Dirac delta function to model a point loading on engineering structures.

When a bending occurs on the notched beam due to an external force, a slope discontinuity (opening fracture mode) occurs at the notch position. The effect of an open notch can thus be modelled by the discontinuity in the slope of the deflection profile of the beam at the notch position. The model can be introduced by separating the notched beam into 4 sections shown in FIG. 13 by considering the piezoelectric bonded areas, 2 and 3, connected at the two ends with the non-bonded parts 1 and 4. The sections 2 and 3 are connected at the notch position in the thickness direction. The total change of the slope at the notch position is modelled as follow:

w₃′|_{x=l+l1/2}−w₂′|_{x=l+l1/2}−ΘLw₂″|_{x=l+l1/2}, (1′)

where w₁˜w₄ are the deflection of the sections 1˜4 of the notched beam, parameter Θ represents the additional non-dimensional flexibility of the beam due to the notch, which is defined as a function of the notch depth and calculated from fracture mechanics and Castigliano's theorem,

$$Θ = 6 π \frac{H}{L} {\int }_{0}^{d / H} {x ( \frac{0.923 + 0.199 {( 1 - sin ( \frac{π}{2} x ) )}^{4}}{cos ( \frac{π}{2} x )} )}^{2} \frac{tan ( \frac{π}{2} x )}{\frac{π}{2} x} d x .$$

The stress concentration at the notch tip may cause the growth of the notch leading to a possible failure of the whole beam structure. The notched structure can be repaired by applying a piezoelectric patch to remove or decrease the slope discontinuity by applying a bending moment owing to its electromechanical effect at the both sides of the notch.

An example of a feedback repair of the notched beam is illustrated below. The piezoelectric layer shown in FIG. 13 can be separated into a sensor and an actuator along its width direction. Assume that the piezoelectric sensor and actuator are with the same length of l₁ and mounted above the same area of the beam.

The electrical charge generated on the surface of the piezoelectric sensor, which is perfectly bonded on a bending beam, is given as follow:

$$Q = - {e}_{31} {\int }_{l}^{l + {l}_{1}} {b}_{s} ( \frac{H + {h}_{1}}{2} ) \frac{{d}^{2} w}{d {x}^{2}} d x , \qquad ( {3}^{′} )$$

where e₃₁ is the piezoelectric constant, bₛ is the width of the piezoelectric sensor and w is the transverse displacement of the notched beam. The corresponding output voltage of the piezoelectric sensor, Vₒ, can be written as:

$${V}_{o} = \frac{Q}{{C}_{v}} = - \frac{{e}_{31} ( H + {h}_{1} )}{2 {C}_{v}^{′}} {\int }_{l}^{l + {l}_{1}} \frac{{d}^{2} w}{d {x}^{2}} d x , \qquad ( {4}^{′} )$$

where Cᵥ is the electrical capacity of the piezoelectric sensor and C′ᵥ is the electric capacity per unit width of the piezoelectric sensor (C′ᵥ=Cᵥ/bₛ).

A gain factor, g, can be multiplied to the output voltage of the piezoelectric sensor to represent the actuation voltage applied to the piezoelectric actuator. The actuation voltage, Vₐ, is thus given by:

$${V}_{a} = {gV}_{o} = - g \frac{{e}_{31} ( H + {h}_{1} )}{2 {C}_{v}^{′}} {\int }_{l}^{l + {l}_{1}} \frac{{d}^{2} w}{d {x}^{2}} d x .$$

When the actuation voltage, Vₐ, is applied to the piezoelectric actuator, a bending moment induced at the two ends of the piezoelectric actuator can be obtained by,

$$Me = S \cdot \frac{H - {h}_{1}}{2} = - g \cdot {d}_{31} {e}_{31} \frac{{EHb}_{a} ( {H}^{2} - {h}_{1}^{2} )}{4 {C}_{v}^{′} {h}_{1} ( ψ + α )} {\int }_{l}^{l + {l}_{1}} \frac{{d}^{2} w}{d {x}^{2}} d x = R \cdot {\int }_{l}^{l + {l}_{1}} \frac{{d}^{2} w}{d {x}^{2}} d x , \qquad ( {6}^{′} )$$

where S is the shear force generated at the interface between the piezoelectric actuator and the host beam.

$$S = \frac{{EHb}_{a}}{ψ + α} {d}_{31} {V}_{a} / {h}_{1} .$$

E is the Young's modulus of the host beam, bₐ is the width of the piezoelectric actuator, and ψ is given as EH/Eₚh₁. Eₚ is the equivalent Young's modulus of the piezoelectric patches, d₃₁ is the piezoelectric charge coefficient and α=6 when a bending bar is considered. R is defined as the repair coefficient and expressed as:

$$R = - g \cdot {d}_{31} {e}_{31} \frac{{EHb}_{a} ( {H}^{2} - {h}_{1}^{2} )}{4 {C}_{v}^{′} {h}_{1} ( ψ + α )} . \qquad ( {7}^{′} )$$

### Determination of the Actuation Voltage

To repair the notched beam, the slope discontinuity at the notch position of the beam during the vibration is targeted to be erased by the repair moment generated by the piezoelectric actuator. The dynamic response of the notched beam bonded with the piezoelectric sensor and actuator can be solved via the Euler-Bernoulli beam theory. From the dynamic response of the notched beam, the actuation voltage on the actuator can be identified by searching for a repair coefficient, R, that leads to reduction of the slope difference between the two sides of the notch.

The process to find the actuation voltage for the repair purpose is illustrated as follows.

Based on the Euler-Bernoulli beam theory, the non-dimensional expressions of the vibration governing equation for the first and fourth sections can be expressed as:

$$\begin{matrix}\frac{{d}^{4} \overline{{W}_{1}}}{d {\overline{x}}^{4}} + {\overline{{ω}_{n}}}^{2} \overline{{W}_{1}} = 0 , ( 0 \leq \overline{x} \leq l / L ) & ( {8}^{′} ) \\ \frac{{d}^{4} \overline{{W}_{4}}}{d {\overline{x}}^{4}} + {\overline{{ω}_{n}}}^{2} \overline{{W}_{4}} = 0 , ( ( l + {l}_{1} ) / L \leq \overline{x} \leq 1 ) & ( {9}^{′} )\end{matrix}$$

where x̅ is the non-dimensional expression of the position on the notched beam

$$( \overline{x} = \frac{x}{L} ) ,$$

and W̅₁ and W̅₄ are the non-dimensional expression of the amplitude of the mode functions of the first and fourth sections of the beam

$$( {\overline{W}}_{1} = \frac{{W}_{1}}{L} , \overline{{W}_{4}} = \frac{{W}_{4}}{L} ) .$$

Let the non-dimensional frequency is expressed by

$$\overline{{ω}_{n}} = \sqrt{\frac{ρ {bHL}^{4} {ω}_{n}^{2}}{EI}} ,$$

where ωₙ is the resonant vibration angular velocity of the structure at the nth mode; ρ is the density of the host beam. The non-dimensional governing equations for the second and third sections, which are bonded with piezoelectric patches, are given as follow:

$$\begin{matrix}\frac{{d}^{4} \overline{{W}_{2}}}{d {\overline{x}}^{4}} + \frac{P}{Q} {\overline{{ω}_{n}}}^{2} \overline{{W}_{2}} = 0 , ( l / L \leq \overline{x} \leq ( l + {l}_{1} / 2 ) / L ) & ( {10}^{′} ) \\ \frac{{d}^{4} \overline{{W}_{3}}}{d {\overline{x}}^{4}} + \frac{P}{Q} {\overline{{ω}_{n}}}^{2} \overline{{W}_{3}} = 0 , ( ( l + {l}_{1} / 2 ) / L \leq \overline{x} \leq ( l + {l}_{1} ) / L ) where \\ \overline{{W}_{2}} = \frac{{W}_{2}}{L} , \overline{{W}_{3}} = \frac{{W}_{3}}{L} , P = \frac{{m}^{′}}{ρ Hb} and Q = \frac{{( EI )}^{′}}{EI} & ( {11}^{′} )\end{matrix}$$

m′ and (EI)′ are the equivalent mass and EI of sections 2 and 3 given by:

$${m}^{′} = ρ Hb + {ρ}^{′} {h}_{1} ( {b}_{s} + {b}_{a} ) \\ {( EI )}^{′} = E ( \frac{{( H - {h}_{1} )}^{3}}{24} + \frac{{( H + {h}_{1} )}^{3}}{24} ) b + {E}_{p} ( \frac{{( H - {h}_{1} )}^{3}}{24} - \frac{{( H + {h}_{1} )}^{3}}{24} ) ( {b}_{s} + {b}_{a} ) \qquad ( {12}^{′} )$$

From Equations 8′˜11′, the non-dimensional free vibration solutions of the notched beam bonded with piezoelectric patches can be obtained to be:

$$\overline{{W}_{1}} = {C}_{1} cos \sqrt{\overline{{ω}_{n}}} \overline{x} + {C}_{2} sin \sqrt{\overline{{ω}_{n}}} \overline{x} + {C}_{3} cosh \sqrt{\overline{{ω}_{n}}} \overline{x} + {C}_{4} sinh \sqrt{\overline{{ω}_{n}}} \overline{x} ( 0 \leq \overline{x} \leq l / L ) \\ \overline{{W}_{2}} = {C}_{5} cos \sqrt{\overline{{ω}_{n}}} {( \frac{P}{Q} )}^{1 / 4} \overline{x} + {C}_{6} sin \sqrt{\overline{{ω}_{n}}} {( \frac{P}{Q} )}^{1 / 4} \overline{x} + {C}_{7} cosh \sqrt{\overline{{ω}_{n}}} {( \frac{P}{Q} )}^{1 / 4} \overline{x} + {C}_{8} sinh \sqrt{\overline{{ω}_{n}}} {( \frac{P}{Q} )}^{1 / 4} \overline{x} ( l / L \leq \overline{x} \leq ( l + {l}_{1} / 2 ) / L ) \\ \overline{{W}_{3}} = {C}_{9} cos \sqrt{\overline{{ω}_{n}}} {( \frac{P}{Q} )}^{1 / 4} \overline{x} + {C}_{10} sin \sqrt{\overline{{ω}_{n}}} {( \frac{P}{Q} )}^{1 / 4} \overline{x} + {C}_{11} cosh \sqrt{\overline{{ω}_{n}}} {( \frac{P}{Q} )}^{1 / 4} \overline{x} + {C}_{12} sinh \sqrt{\overline{{ω}_{n}}} {( \frac{P}{Q} )}^{1 / 4} \overline{x} ( ( l + {l}_{1} / 2 ) / L \leq \overline{x} \leq ( l + {l}_{1} ) / L ) \\ {\overline{W}}_{4} = {C}_{13} cos \sqrt{\overline{{ω}_{n}}} \overline{x} + {C}_{14} sin \sqrt{\overline{{ω}_{n}}} \overline{x} + {C}_{15} cosh \sqrt{\overline{{ω}_{n}}} \overline{x} + {C}_{16} sinh \sqrt{\overline{{ω}_{n}}} \overline{x} ( ( l + {l}_{1} ) / L \leq \overline{x} \leq 1 ) , \qquad ( {13}^{′} )$$

where C₁˜C₁₆ are unknown constants.

Submitting Equations 6′ and 13′ into the boundary conditions of the notched cantilever beam bonded with the piezoelectric layer leads to sixteen linear equations which can be solve and the nth non-dimensional solutions of the normal mode expression of the beam, W̅₁( x̅,n)˜ W̅₄( x̅,n), corresponding with the nth non-dimensional resonance angular velocities, ω̅ₙ, for a given repair coefficient, R.

The non-dimensional forced vibration solution of the notched cantilever beam bonded with piezoelectric layer shown in FIG. 13 can be expressed as,

$$\overline{{w}_{1 \sim 4}} ( \overline{x} , t ) = {\sum }_{n = 1}^{∞} {W}_{1 ∼ 4} ( \overline{x} , n ) \overline{q} ( t , n ) , \qquad ( {14}^{′} )$$

where q̅(t,n) is the non-dimensional generalized coordinate in the nth mode.

$$Determine \overline{q} ( t , n ) = \frac{\overline{F} \overline{{W}_{4}} ( 1 , n ) sin ( \overline{{ω}^{′}} t )}{{\int }_{0}^{1} \overline{{W}_{1 \sim 4}} ( \overline{x} , n ) d x ( {\overline{ω}}_{n}^{2} - {\overline{{ω}^{′}}}^{2} )} ,$$

when a point force, f(x, t)=F sin(ω′t)δ(x−L), is applied at the free end of the cantilever beam, where

$$\overline{{ω}^{′}} = \sqrt{\frac{ρ {bHL}^{4} {ω}^{′2}}{EI}} and \overline{F} = \frac{{FL}^{3}}{EI} .$$

The non-dimensional vibration solution of the piezoelectric bonded notched cantilever beam subjected to a dynamic force applied at its free end can be expressed as:

$$\overline{{w}_{1 \sim 4}} ( \overline{x} , t ) = {\sum }_{n = 1}^{∞} \overline{{W}_{1 ∼ 4}} ( \overline{x} , n ) \frac{\overline{F} \overline{{W}_{4}} ( 1 , n ) sin ( \overline{{ω}^{′}} t )}{{\int }_{0}^{1} \overline{{W}_{1 \sim 4}} ( \overline{x} , n ) d \overline{x} ( {\overline{ω}}_{n}^{2} - {\overline{{ω}^{′}}}^{2} )} . \qquad ( {15}^{′} )$$

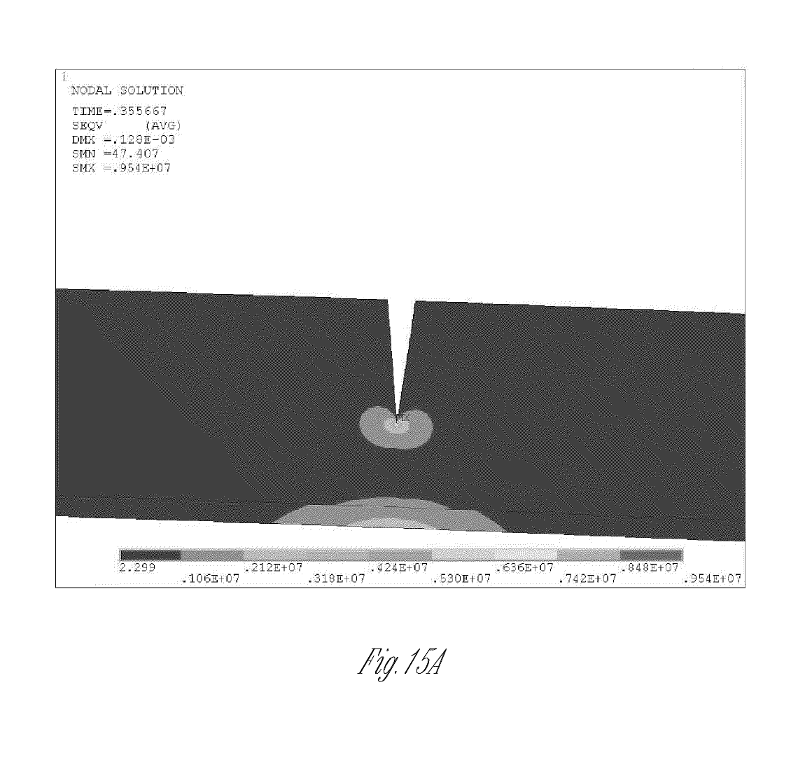

In numerical simulations, only the first three modes (n=1˜3) are considered to get the vibration deflection of the piezoelectric bonded notched cantilever beam subjected to the dynamic loading with a low frequency. Submitting the solutions of the normal mode expression of the beam, W̅₁(x,n)˜ W̅₄(x,n) (n=1˜3), corresponding to a given repair coefficient, R, into Equation 15′, obtain the vibration deflection of the piezoelectric bounded notched beam. The relationship between the repair coefficient and the slope of the vibration deflection of the beam can thus be determined accordingly based on the right side of Equation 1′, and a coefficient can thus be identified. In the set-up in FIG. 14, the amplitude and angular velocity of the non-dimensional dynamic external force are assumed to be 0.2 and 0.03, respectively ( F̅=0.2, ω̅′̅=0.03). FIG. 14 illustrates the largest non-dimensional slope discontinuities at the notch position of the beam during vibrations versus the repair coefficients.

The non-dimensional slope discontinuity at the notch position approaches zero with the repair coefficient of 366.6. From Equation 7′, the gain factor, g, can thus be found for the repair of the notched beam given certain dimensions and material properties of the piezoelectric patches. The actuation voltage is obtained from Equation 5′.

### FEM Simulations

An FEM model can be built to verify the feedback repair of the notched cantilever beam. The structure dimensions and material properties of the notched beam and the piezoelectric layer are given in Table 1. A transversal dynamic point force with an angular velocity of 1000 rad/s is applied at the free end of the cantilever beam. The amplitude of the point force at the free end of the beam is set as 20N. Normal plane element plane and coupled field element plane are used to mesh the notched host beam structure and the piezoelectric layer, respectively. From Equation 7′ and the repair coefficient given in FIG. 14, the satisfied gain factor, g, can be found given the structural dimensions and the material properties in Table 1.

TABLE 1
Material and geometric properties
of the piezoelectric coupled beam.

| | | Notched Host | Piezoelectric |
|---|---|---|---|
| | | Beam | patches |
| Parameters | | (Aluminum) | (PZT4) |
| Young's module | (N/m²) | E = 69 × 10⁹ | Eₚ = 78 × 10⁹ |
| Mass density | (kg/m³) | 2.8 × 10³ | 7.5 × 10³ |
| e₃₁ | (C/m²) | — | −2.8 |
| d₃₁ | (C/N) | — | −1.28 × 10⁻¹⁰ |
| Cv | (nF) | — | 0.75 for the piezoelectric |
| | | | patch with the dimension |
| | | | of 0.01 m × 0.06 m × |
| | | | 0.0003 m |
| L | (m) | 0.365 | — |
| l₁ | (m) | — | 0.06 |
| H | (m) | 0.003 | — |
| h₁ | (m) | — | 0.0003 |
| l | (m) | 0.03 | — |
| d | (m) | 0.0018 | — |
| b | (m) | 0.03 | — |
| bₛ | (m) | — | 0.01 |
| bₐ | (m) | — | 0.01 |

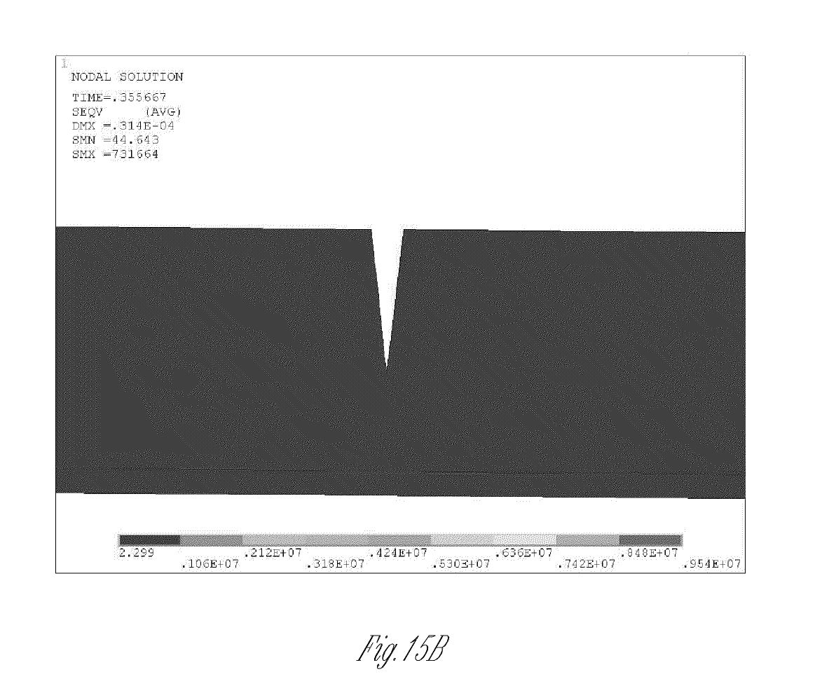

FIGS. 15A and 15B illustrate the Von Mises stress distribution around the notch tip at 0.356 s of the vibration of the notched cantilever beam before and after repair. As shown, the Von Mises stress at the notch tip point O is decreased from 9.5 MPa to 0.4 MPa, when the gain factor is set as 74, which is provided by the analytical model. 95.8% reduction of the stress concentration can be found at the notch tip of the beam after repair. The effectiveness of the analytical model can be shown by the FEM simulation. FIG. 15A illustrates gain factor 0 and FIG. 15B illustrates gain factor 74.

### Experimental Realization

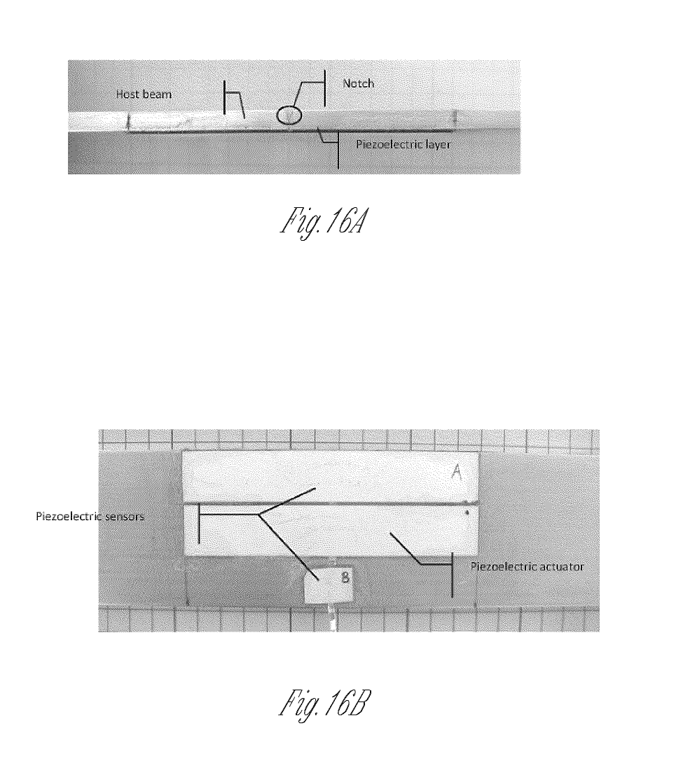

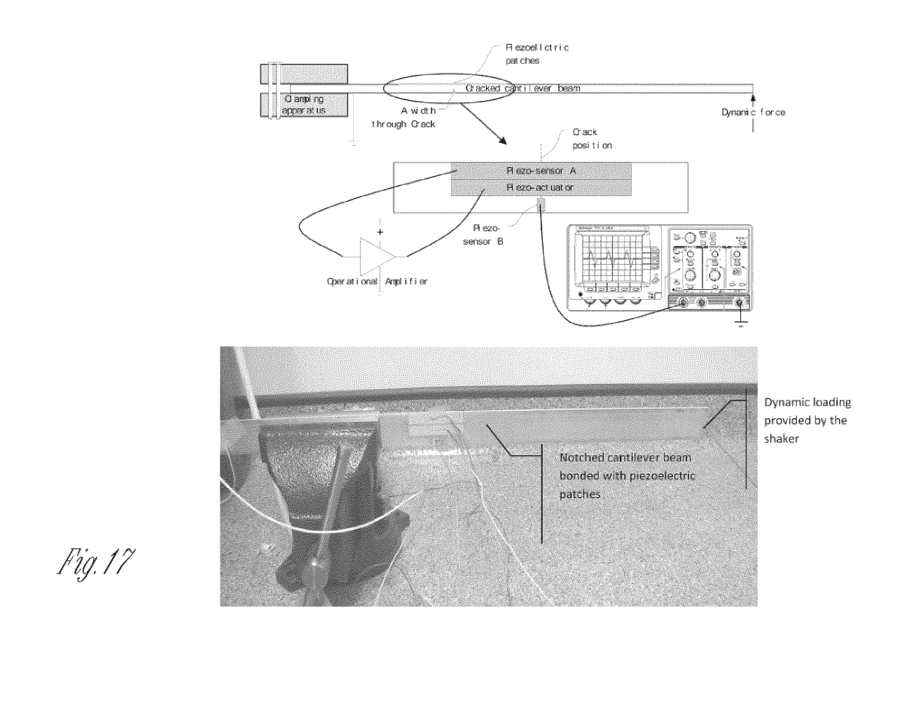

Experiments involving a feedback repair can be conducted based on the electromechanical effect of the piezoelectric material. FIG. 16A shows a front view of a piezoelectric actuator and sensors mounted on the opposite surface of the notch area of the beam. FIG. 16B shows the piezoelectric sensors and actuator bonded above the notch area. In this example, the width of the notch beam is 0.03 m. The piezoelectric actuator and piezoelectric sensor ‘A’ are with the same length of 0.06 m and width of 0.01 m. The width and length of the piezoelectric sensor ‘B’ is 0.007 m and 0.01 m, respectively. A large piezoelectric sensor ‘A’ is used to measure the vibration of the beam around the notch area and generate a large output voltage and the corresponding actuation voltage with certain gain factor. The small piezoelectric sensor ‘B’ is mounted just above the notch position to provide an accurate measurement of the slope difference between the two sides of the notch to show the effectiveness of the repair strategy. A final actuation voltage on the piezoelectric actuator can be obtained when the output voltage from piezoelectric sensor ‘B’ approaches to zero.

### Experiment Setup

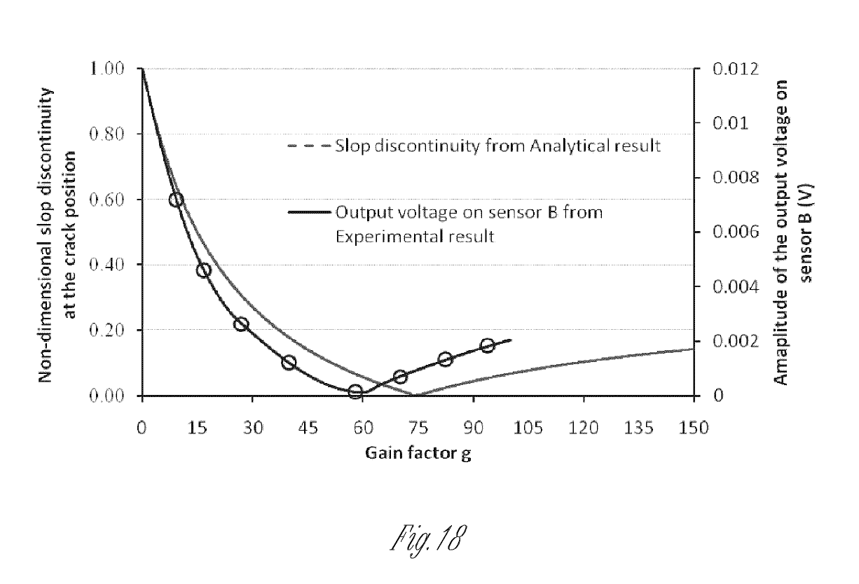

FIG. 17 illustrates an experiment setup of the notched beam bonded with the piezoelectric patches. The dimensions and material properties of the notched beam and the piezoelectric patches are given in Table 1. An aluminum notched beam bonded with piezoelectric patches is fixed on a clamping apparatus, and a steady sinusoidal force excitation is applied at the right end of the cantilever beam by a shaker. An adjustable operational amplifier, whose gain is variable from 0 to 120, provides an adaptable gain factor to the output voltage from the surface of the piezoelectric sensor ‘A’. As shown in FIGS. 16A and 16B, the aluminum beam bonded with piezoelectric patches is ground connected, and the surface of the piezoelectric sensor ‘A’ is connected with the input pad of the operational amplifier while the output pad of the operational amplifier is connected to the surface of the piezoelectric actuator to build the feedback repair circuit. The voltage signal from the surface of the piezoelectric sensor ‘B’ is captured by the oscilloscope software to illustrate the repair effect of the feedback repair.

When a steady sinusoidal force excitation is applied to the free end of the cantilever beam, the dynamic voltage signal representing the bending of the vibrating beam is generated on the piezoelectric sensors. The output voltages from the piezoelectric sensors ‘A’ and ‘B’ and the actuation voltages applied to the piezoelectric actuator with the different gain factors can be shown on an oscilloscope. To avoid large deflection, which may damage the piezoelectric patches, and make sure the bonding layer between piezoelectric patches and the host beam would not be damaged by the cyclic loading; a small sinusoidal force excitation with amplitude of 0.02N can be applied on the free end of the cantilever beam. The angular velocity is set to be 1000 rad/s. Data can be collected to show the voltage signal from the piezoelectric sensor ‘A’ and ‘B’, respectively as well as the actuation voltage applied to the piezoelectric actuator. Based on Equation 4°, the output voltage from piezoelectric sensor ‘B’ indicates the slope discontinuity at the notch position. Thus, the output voltage generated on the piezoelectric sensor ‘B’ can be used as the criterion to evaluate the repair efficiency.

In one example, the amplitude of the output voltage generated on the piezoelectric sensor ‘B’ is 1.2e-2V when there is no actuation voltage applied to the piezoelectric actuator, or before repair is conducted. When the gain factor applied to the output voltage from the piezoelectric sensor ‘A’ is set to be 60, an amplitude of the actuation voltage of 1.1e-1V is generated and applied to the piezoelectric actuator, and the output voltage from the piezoelectric sensor ‘B’ approaches to zero. At this state, the slope discontinuity on the notch position is substantially removed and the notch effect is removed accordingly. In one example, as the gain factor is increased to 85, the amplitude of the actuation voltage becomes 1.3e-1V, but the amplitude of the output voltage on the piezoelectric sensor ‘B’ is found to grow back to 1.8e-3V. The notch effect can be removed when the gain factor increases to a certain value and a re-growth of the discontinuity of the slope difference between the two sides of the notch will be found for larger gain factors. The repair is accomplished using a particular value of the gain factor. This is consistent with result given by the analytical model.

FIG. 18 illustrates slope discontinuities at the notch position from the analytical simulation and the amplitude of the output voltage generated on the piezoelectric sensor ‘B’ given by experimental data versus the gain factors. The interpolation curve of the experimental data has the same trend with the analytical result. Differences can be the result of segmentation of the beam and the Euler-Bernoulli beam theory used for the modeling and experiment error. With the gain factor of 74, which is the gain factor provided by the analytical model, the output voltage of piezoelectric sensor B can be reduced to 7e-4 V, which is 5.8% of the reading of the sensor before repair.

An example of the present subject matter includes a feedback repair process for a notched cantilever beam structure subjected to a dynamic loading by the use of piezoelectric patches. The electromechanical effect of the piezoelectric material is employed to induce a repair bending moment on the both sides of the notch with an actuation voltage to reduce the stress concentration at the notch tip. An analytical model and an FEM analysis can be conducted. In one example, compared with the notched beam before repair, the stress concentration at the notch tip of the beam after repair is found to be reduced by 95.8% in the FEM simulation. A piezoelectric sensor mounted above the notch position can be used to provide a measurement of the reduction of the slope discontinuity at the notch. The slope discontinuity at the notch position approaches zero when the designed gain factor is applied.

When the gain factor is set to be a value given by an analytical model, the slope discontinuity at the notch position is reduced by approximately 95% from experiments.

### Additional Notes

Example 1 includes subject matter (such as a system) comprising a piezoelectric patch, a data source, a processor, and a power supply. The piezoelectric patch has a planar surface configured for affixation to a structural plate and has a plurality of segments. Each segment has a pair of electrodes.

The data source is configured to provide data corresponding to the plate. The processor is coupled to the data source and is configured to execute an algorithm to determine a voltage corresponding to each segment of the plurality of segments. The power supply has a plurality of outputs coupled to the plurality of pairs of electrodes. The processor is configured to provide a signal to modulate the outputs.

In Example 2, the subject matter of Example 1 can optionally provide for the plurality of segments in parallel alignment.

In Example 3, the subject matter of any one or any combination of Examples 1-2 can optionally provide wherein a first segment of the plurality of segments is electrically isolated from a second segment of the plurality of segments.

In Example 4, the subject matter of any one or any combination of Examples 1-3 can optionally provide wherein the data source includes a model.

In Example 5, the subject matter of any one or any combination of Examples 1-4 can optionally provide wherein the data source includes a sensor coupled to the plate.

In Example 6, the subject matter of any one or any combination of Examples 1-5 can optionally provide wherein the algorithm includes a numeric model.

In Example 7, the subject matter of any one or any combination of Examples 1-6 can optionally provide wherein the processor is coupled to a user input.

In Example 8, the subject matter of any one or any combination of Examples 1-7 can optionally provide wherein the user input is configured to receive an estimated load.

In Example 9, the subject matter of any one or any combination of Examples 1-8 can optionally provide wherein the processor is configured to modulate a voltage of the outputs.

Example 10 includes subject matter (such as a patch) comprising a piezoelectric material and a plurality of pairs of electrodes. The piezoelectric material has a planar surface and the planar surface is configured for affixation to a structural plate. The plurality of pairs of electrodes is coupled to the piezoelectric material. The plurality of pairs of electrodes corresponds to a plurality of segments of the piezoelectric material. Each segment is electrically isolated from at least one other segment.

In Example 11, the subject matter of Example 10 can optionally include wherein a length of the patch is substantially equal to a width of the patch.

In Example 12, the subject matter of any one or any combination of Examples 10 or 11 can optionally include wherein the patch is configured to overlay a delamination of the plate.

In Example 13, the subject matter of any one or any combination of Examples 10-12 can optionally include wherein the piezoelectric material includes ten segments.

In Example 14, the subject matter of any one or any combination of Examples 10-13 can optionally include wherein the segments are in parallel alignment.

In Example 15, the subject matter of any one or any combination of Examples 10-14 can optionally include wherein the electrodes are configured to couple with a power supply.

Example 16 includes subject matter (such as a method) comprising affixing a piezoelectric patch, determining a plurality of voltages, and providing the plurality of voltages. This can include affixing the piezoelectric patch to a structural plate. The patch has a plurality of pairs of electrical nodes. Determining a plurality of voltages provides that each pair of electrical nodes corresponds to a particular voltage of the plurality of voltages. The plurality of voltages is based on a load corresponding to the plate. In addition, the method includes providing the plurality of voltages to the patch.

In Example 17, the subject matter of Example 16 can optionally include bonding a contact surface of the patch with the plate.

In Example 18, the subject matter of any one or any combination of Examples 16 or 17 can optionally include wherein determining the plurality of voltages includes executing an algorithm using a processor.

In Example 19, the subject matter of any one or any combination of Examples 16-18 can optionally include wherein determining the plurality of voltages includes executing an algorithm based on a numeric model.

In Example 20, the subject matter of any one or any combination of Examples 16-19 can optionally include wherein determining the plurality of voltages includes estimating at least one of a tensile force and a compressive force corresponding to the load.

In Example 21, the subject matter of any one or any combination of Examples 16-20 can optionally include estimating at least one of a tensile force and a compressive force corresponding to the load includes estimating a force corresponding to each of pair of electrical nodes.

In Example 22, the subject matter of any one or any combination of Examples 16-21 can optionally include wherein determining the plurality of voltages includes determining a force distribution corresponding to the load.

In Example 23, the subject matter of any one or any combination of Examples 16-22 can optionally include wherein determining the plurality of voltages includes determining a force distribution along a delaminated edge of the plate.

In Example 24, the subject matter of any one or any combination of Examples 16-23 can optionally include wherein determining the plurality of voltages includes executing a process based on a finite element model.

In Example 25, the subject matter of any one or any combination of Examples 16-24 can optionally include wherein determining the plurality of voltages includes determining a location of the patch relative to a location of a delamination of the plate.

In Example 26, the subject matter of any one or any combination of Examples 16-25 can optionally include wherein determining the plurality of voltages includes receiving data corresponding to the load.

In Example 27, the subject matter of any one or any combination of Examples 16-26 can optionally include wherein receiving data includes receiving a signal from a sensor affixed to at least one of the patch and the plate.

In Example 28, the subject matter of any one or any combination of Examples 16-27 can optionally include wherein receiving the signal from the sensor includes receiving displacement data or receiving load data.

In Example 29, the subject matter of any one or any combination of Examples 16-28 can optionally include wherein providing the plurality of voltages includes modulating a power supply.

These non-limiting examples can be combined in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or an are used, as is common in patent documents, to include one or more than one, independent of any other instances or usages of “at least one” or “one or more.” In this document, the term or is used to refer to a nonexclusive or, such that “A or B” includes “A but not but not A,” and “A and B” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A system comprising:
a piezoelectric patch having a planar surface configured for affixation to a structural plate, and having a plurality of segments, each segment having a pair of electrodes;
a data source configured to provide data corresponding to the plate;
a processor coupled to the data source and configured to execute an algorithm to determine a voltage corresponding to each segment of the plurality of segments; and
a power supply having a plurality of outputs coupled to the plurality of pairs of electrodes, the processor configured to provide a signal to modulate the outputs.

2. The system of claim 1 wherein a first segment of the plurality of segments is electrically isolated from a second segment of the plurality of segments.

3. The system of claim 1 wherein the data source includes a sensor coupled to the plate.

4. The system of claim 1 further including a user input coupled to the processor, the user input configured to receive an estimated load.

5. The system of claim 1 wherein the processor is configured to modulate a voltage of the outputs.

6. A patch comprising:
a piezoelectric material having a planar surface, the planar surface configured for affixation to a structural plate; and
a plurality of pairs of electrodes coupled to the piezoelectric material, the plurality of pairs of electrodes corresponding to a plurality of segments of the piezoelectric material, wherein each segment is electrically isolated from at least one other segment.

7. The patch of claim 6 wherein the segments are in parallel alignment.

8. A method comprising:
affixing a piezoelectric patch to a structural plate, the patch having a plurality of pairs of electrical nodes;
determining a plurality of voltages, wherein each pair of electrical nodes corresponds to a particular voltage of the plurality of voltages, the plurality of voltages based on a load corresponding to the plate; and
providing the plurality of voltages to the patch.

9. The method of claim 8 wherein determining the plurality of voltages includes executing an algorithm using a processor.

10. The method of claim 8 wherein determining the plurality of voltages includes executing an algorithm based on a numeric model.

11. The method of claim 8 further including estimating at least one of a tensile force and a compressive force corresponding to the load and estimating a force corresponding to each of the pair of electrical nodes.

12. The method of claim 8 wherein determining the plurality of voltages includes receiving data corresponding to the load.

13. The method of claim 12 wherein receiving data includes receiving a signal from a sensor affixed to at least one of the patch and the plate.

14. The method of claim 8 wherein providing the plurality of voltages includes modulating a power supply.
